(19) United States
(12) Patent Application Publication
(10) Pub. No.: US 2025/0248120 A1
(43) Pub. Date: Jul. 31, 2025

(54) ARRAY SUBSTRATE AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Wenzhe Cai, Beijing (CN); Mengmeng Du, Beijing (CN); Yao Huang, Beijing (CN); Rong Wang, Beijing (CN); Yi He, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/689,331

(22) PCT Filed: Mar. 28, 2023
(86) PCT No.: PCT/CN2023/084450

§ 371 Date: Mar. 5, 2024

(51) Int. Cl. H10D 86/40

(52) U.S. Cl. CPC H10D 86/441; H10D 86/421

(57) ABSTRACT

An array substrate is provided. The array substrate includes a plurality of first gate lines, a plurality of second gate lines, and a plurality of pixel driving circuits. The array substrate includes a first semiconductor material layer and a second semiconductor material layer on a side of the first semiconductor material layer away from a base substrate. The first semiconductor material layer includes at least active layers of the driving transistor and the data write transistor. The second semiconductor material layer includes at least an active layer of the compensating transistor. A first parasitic capacitor is formed between the second semiconductor material layer and the respective first gate line. A second parasitic capacitor is formed between the first node connecting line and the respective second gate line. A ratio of a capacitance of the first parasitic capacitor to a capacitance of the second parasitic capacitor is greater than 2.3.

### TECHNICAL FIELD

The present invention relates to display technology, more particularly, to an array substrate and a display apparatus.

### BACKGROUND

Organic Light Emitting Diode (OLED) display is one of the hotspots in the field of flat panel display research today. Unlike Thin Film Transistor-Liquid Crystal Display (TFT-LCD), which uses a stable voltage to control brightness, OLED is driven by a driving current required to be kept constant to control illumination. The OLED display panel includes a plurality of pixel units configured with pixel-driving circuits arranged in multiple rows and columns. Each pixel-driving circuit includes a driving transistor having a gate terminal connected to one gate line per row and a drain terminal connected to one data line per column. When the row in which the pixel unit is gated is turned on, the switching transistor connected to the driving transistor is turned on, and the data voltage is applied from the data line to the driving transistor via the switching transistor, so that the driving transistor outputs a current corresponding to the data voltage to an OLED device. The OLED device is driven to emit light of a corresponding brightness.

### SUMMARY

In one aspect, the present disclosure provides an array substrate, comprising a plurality of first gate lines, a plurality of second gate lines, and a plurality of pixel driving circuits; wherein a respective pixel driving circuit of the plurality of pixel driving circuits comprises a driving transistor, a data write transistor, a compensating transistor, a storage capacitor, a first node connecting line connecting a gate electrode of the driving transistor with a first electrode of the compensating transistor; a respective first gate line of the plurality of first gate lines configured to provide a gate scanning signal to the data write transistor; a respective second gate line of the plurality of second gate lines configured to provide a gate scanning signal to the compensating transistor; wherein the array substrate comprises a first semiconductor material layer and a second semiconductor material layer on a side of the first semiconductor material layer away from a base substrate; the first semiconductor material layer comprises at least active layers of the driving transistor and the data write transistor; the second semiconductor material layer comprises at least an active layer of the compensating transistor; a first parasitic capacitor is formed between the second semiconductor material layer and the respective first gate line; a second parasitic capacitor is formed between the first node connecting line and the respective second gate line; wherein a ratio of a capacitance of the first parasitic capacitor to a capacitance of the second parasitic capacitor is greater than 2.3.

Optionally, the ratio of the capacitance of the first parasitic capacitor to the capacitance of the second parasitic capacitor is between 2.3 to 3.5.

Optionally, the first node connecting line crosses over the respective second gate line; in a region where an orthographic projection of the first node connecting line on the base substrate overlaps with an orthographic projection of the respective second gate line on the base substrate, the array substrate is absent of any other conductive component whose orthographic projection on the base substrate overlaps with the orthographic projection of the first node connecting line on the base substrate; and the first node connecting line is in a layer that is spaced apart from the respective second gate line by at least two different insulating layers and a semiconductor material layer.

Optionally, the respective pixel driving circuit further comprises a third gate electrode pad, and a gate connecting pad connecting the third gate electrode pad with the respective second gate line; orthographic projections of the third gate electrode pad and the respective second gate line on the base substrate overlap with an orthographic projection of an active layer of the compensating transistor on the base substrate; the third gate electrode pad, the gate connecting pad, and the respective second gate line, and the active layer of the compensating transistor are in four different layers, respectively.

Optionally, the respective second gate line is in a second gate metal layer comprising a second capacitor electrode of the storage capacitor; the active layer of the compensating transistor is in the second semiconductor material layer on a side of the second gate metal layer away from the base substrate; the third gate electrode pad is in a third gate metal layer on a side of the second semiconductor material layer away from the second gate metal layer; and the gate connecting pad is in a first signal line layer on a side of the third gate metal layer away from the second semiconductor material layer.

Optionally, the gate connecting pad is in a second gate metal layer comprising a second capacitor electrode of the storage capacitor; the active layer of the compensating transistor is in the second semiconductor material layer on a side of the second gate metal layer away from the base substrate; the third gate electrode pad is in a third gate metal layer on a side of the second semiconductor material layer away from the second gate metal layer; and the respective second gate line is in a first signal line layer on a side of the third gate metal layer away from the second semiconductor material layer.

Optionally, the respective second gate line is in a second gate metal layer comprising a second capacitor electrode of the storage capacitor; the first electrode of the compensating transistor is in the second semiconductor material layer on a side of the second gate metal layer away from the base substrate; and the first node connecting line is in a first signal line layer on a side of the second semiconductor material layer away from the second gate metal layer.

Optionally, the first node connecting line is in a first gate metal layer comprising a first capacitor electrode of the storage capacitor; the first electrode of the compensating transistor is in the second semiconductor material layer on a side of the first gate metal layer away from the base substrate; and the respective second gate line is in a first signal line layer on a side of the second semiconductor material layer away from the first gate metal layer.

Optionally, the first node connecting line and the first capacitor electrode are parts of a unitary structure.

Optionally, the respective pixel driving circuit further comprises a node connecting pad in the first signal line layer comprising the respective second gate line; and the node connecting pad connects the first node connecting line in the first gate metal layer with the first electrode of the compensating transistor in the second semiconductor material layer.

Optionally, the node connecting pad is connected to the first node connecting line through an eighth via, and connected to the first electrode of the compensating transistor through a seventh via; the seventh via extends through a passivation layer and a second inter-layer dielectric layer; and the eighth via extends through the passivation layer, the second inter-layer dielectric layer, a first inter-layer dielectric layer, and an insulating layer.

Optionally, the respective second gate line comprises a first portion and a second portion; an orthographic projection of the first portion on the base substrate at least partially overlaps with an orthographic projection of an active layer of the compensating transistor on the base substrate, and is non-overlapping with an orthographic projection of the first node connecting line on the base substrate; an orthographic projection of the second portion on the base substrate at least partially overlaps with the orthographic projection of the first node connecting line on the base substrate, and is non-overlapping with an orthographic projection of the active layer of the compensating transistor on the base substrate; the respective second gate line extends along a first direction; the first portion has a first average line width where the first portion crosses over the active layer of the compensating transistor, along a second direction perpendicular to the first direction; the second portion has a second average line width where the second portion crosses over the first connecting line, along the second direction; and the first average line width is greater than the second average line width.

Optionally, the array substrate further comprises a plurality of first voltage supply lines and a plurality of light emitting control signal lines; wherein a respective pixel driving circuit of the plurality of pixel driving circuits comprises a first light emitting control transistor and a voltage connecting pad; wherein the voltage connecting pad comprises a main portion and an extension portion extending away from the main portion; the main portion connects a respective first voltage supply line of the plurality of first voltage supply lines with a second capacitor electrode of the storage capacitor; the extension portion connects the main portion with a first electrode of the first light emitting control transistor; and the extension portion crosses over a respective light emitting control signal line of the plurality of light emitting control signal lines.

Optionally, the main portion includes a first main part and a second main part; the first main part connects the respective first voltage supply line with the second capacitor electrode; an orthographic projection of the first main part on a base substrate at least partially overlaps with an orthographic projection of the second capacitor electrode on the base substrate, and at least partially overlaps with an orthographic projection of the respective first voltage supply line on the base substrate; an orthographic projection of the second main part on the base substrate is non-overlapping with an orthographic projection of the second capacitor electrode on the base substrate, is non-overlapping with an orthographic projection of the respective first voltage supply line on the base substrate, and at least partially overlaps with an orthographic projection of a second electrode of the driving transistor on the base substrate; the first main part has a first average pad width along a direction substantially parallel to the second direction; the second main part has a second average pad width along the direction substantially parallel to the second direction; and the first average pad width is greater than the second average pad width.

Optionally, the respective light emitting control signal line is in a first gate metal layer; the main portion and the extension portion are in a first signal line layer on a side of the first gate metal layer away from the base substrate; the respective first voltage supply line is in a second signal line layer on a side of the first signal line layer away from the first gate metal layer; the respective first voltage supply line is connected to the first main part through a third via extends through a first planarization layer; and the first main part is connected to the second capacitor electrode through a fourth via extending through a passivation layer, a second inter-layer dielectric layer, and a first inter-layer dielectric layer.

Optionally, an orthographic projection of the respective first voltage supply line on the base substrate covers the orthographic projection of the first node connecting line on the base substrate.

Optionally, the respective pixel driving circuit further comprises a first reset transistor; active layers of the compensating transistor and the first reset transistor are in a second semiconductor material layer; and an orthographic projection of the respective first voltage supply line on a base substrate covers an orthographic projection of the active layers of the compensating transistor and the first reset transistor on the base substrate.

Optionally, the array substrate further comprises a plurality of second voltage supply lines, a plurality of fourth reset signal lines, and a plurality of data lines in a same layer as the plurality of first voltage supply lines; the plurality of pixel driving circuits are arranged in columns, including (2k-1)-th column C(2k-1), and (2k)-th column C(2k) of K columns, K and k being positive integers, 1≤k≤K/2; the plurality of fourth reset signal lines are present in the (2k-1)-th column C(2k-1), and are absent in the (2k)-th column C(2k); and the plurality of second voltage supply lines are present in the (2k)-th column C(2k), and are absent in the (2k-1)-th column C(2k-1).

Optionally, the array substrate further comprises a plurality of reset signal lines extending along a direction substantially parallel to a first direction, respectively; the plurality of first voltage supply lines, the plurality of second voltage supply lines, the plurality of fourth reset signal lines, and the plurality of data lines extending along a direction substantially parallel to a second direction; the array substrate comprises an interconnected reset signal network comprising the plurality of fourth reset signal lines and the plurality of reset signal lines; a respective reset signal line of the plurality of reset signal lines is connected to one or more fourth reset signal line of the plurality of fourth reset signal line; and a respective fourth reset signal line of the plurality of fourth reset signal lines is connected to one or more reset signal line of the plurality of reset signal lines.

In another aspect, the present disclosure provides an array substrate, comprising a plurality of first gate lines, a plurality of second gate lines, and a plurality of pixel driving circuits; wherein a respective pixel driving circuit of the plurality of pixel driving circuits comprises a driving transistor, a data write transistor, a compensating transistor, a storage capacitor, a first node connecting line connecting a gate electrode of the driving transistor with a first electrode of the compensating transistor; a respective first gate line of the plurality of first gate lines configured to provide a gate scanning signal to the data write transistor; a respective second gate line of the plurality of second gate lines configured to provide a gate scanning signal to the compensating transistor; wherein the array substrate comprises a first semiconductor material layer and a second semiconductor material layer on a side of the first semiconductor material layer away from a base substrate; the first semiconductor material layer comprises at least active layers of the driving transistor and the data write transistor; the second semiconductor material layer comprises at least an active layer of the compensating transistor; a first parasitic capacitor is formed between the second semiconductor material layer and the respective first gate line; a second parasitic capacitor is formed between the first node connecting line and the respective second gate line; the respective first gate line comprises a respective first gate line first branch in a first gate metal layer and a respective first gate line second branch in a first signal line layer on a side of the first gate metal layer away from the base substrate; the respective first gate line second branch is connected to the respective first gate line first branch through one or more vias; the first parasitic capacitor is formed between the second semiconductor material layer and the respective first gate line first branch and between the second semiconductor material layer and the respective first gate line second branch; and a capacitance of the first parasitic capacitor is greater than at least twice of a capacitance of the second parasitic capacitor.

In another aspect, the present disclosure provides a display apparatus, comprising the array substrate described herein, and one or more integrated circuits connected to the array substrate.

### BRIEF DESCRIPTION OF THE FIGURES

The following drawings are merely examples for illustrative purposes according to various disclosed embodiments and are not intended to limit the scope of the present invention.

FIG. 1 is a plan view of an array substrate in some embodiments according to the present disclosure.

FIG. 2A is a circuit diagram illustrating the structure of a pixel driving circuit in some embodiments according to the present disclosure.

FIG. 2B is a timing diagram illustrating the operation of a pixel driving circuit in some embodiments according to the present disclosure.

FIG. 3A is a diagram illustrating the structure of a pixel driving circuit in an array substrate in some embodiments according to the present disclosure.

FIG. 3B is a diagram illustrating the structure of a first semiconductor material layer in the array substrate depicted in FIG. 3A.

FIG. 3C is a diagram illustrating the structure of a first gate metal layer in the array substrate depicted in FIG. 3A.

FIG. 3D is a diagram illustrating the structure of a second gate metal layer in the array substrate depicted in FIG. 3A.

FIG. 3E is a diagram illustrating the structure of a second semiconductor material layer in the array substrate depicted in FIG. 3A.

FIG. 3F is a diagram illustrating the structure of a third gate metal layer in the array substrate depicted in FIG. 3A.

FIG. 3G is a diagram illustrating vias extending through a first inter-layer dielectric layer in the array substrate depicted in FIG. 3A.

FIG. 3H is a diagram illustrating vias extending through a passivation layer in the array substrate depicted in FIG. 3A.

FIG. 3I is a diagram illustrating the structure of a first signal line layer in the array substrate depicted in FIG. 3A.

FIG. 3J is a diagram illustrating vias extending through a first planarization layer in the array substrate depicted in FIG. 3A.

FIG. 3K is a diagram illustrating the structure of a second signal line layer in the array substrate depicted in FIG. 3A.

FIG. 4A is a cross-sectional view along an A-A′ line in FIG. 3A.

FIG. 4B is a cross-sectional view along a B-B′ line in FIG. 3A.

FIG. 5A is a diagram illustrating the structure of a pixel driving circuit in an array substrate in some embodiments according to the present disclosure.

FIG. 5B is a diagram illustrating the structure of a first semiconductor material layer in the array substrate depicted in FIG. 5A.

FIG. 5C is a diagram illustrating the structure of a first gate metal layer in the array substrate depicted in FIG. 5A.

FIG. 5D is a diagram illustrating the structure of a second gate metal layer in the array substrate depicted in FIG. 5A.

FIG. 5E is a diagram illustrating the structure of a second semiconductor material layer in the array substrate depicted in FIG. 5A.

FIG. 5F is a diagram illustrating the structure of a third gate metal layer in the array substrate depicted in FIG. 5A.

FIG. 5G is a diagram illustrating vias extending through a first inter-layer dielectric layer in the array substrate depicted in FIG. 5A.

FIG. 5H is a diagram illustrating vias extending through a passivation layer in the array substrate depicted in FIG. 5A.

FIG. 5I is a diagram illustrating the structure of a first signal line layer in the array substrate depicted in FIG. 5A.

FIG. 5J is a diagram illustrating vias extending through a first planarization layer in the array substrate depicted in FIG. 5A.

FIG. 5K is a diagram illustrating the structure of a second signal line layer in the array substrate depicted in FIG. 5A.

FIG. 6A is a cross-sectional view along a C-C′ line in FIG. 5A.

FIG. 6B is a cross-sectional view along a D-D′ line in FIG. 5A.

FIG. 7 is a diagram illustrating the structure of a pixel driving circuit in an array substrate in some embodiments according to the present disclosure.

FIG. 8 is a cross-sectional view along an E-E′ line in FIG. 7.

FIG. 9 is a cross-sectional view of a region where a first node connecting line crosses over a respective second gate line first branch and a respective second gate line second branch.

FIG. 10 is a diagram illustrating the structure of a second signal line layer in an array substrate in some embodiments according to the present disclosure.

FIG. 11 illustrates an interconnected reset signal network in some embodiments according to the present disclosure.

FIG. 12 illustrates an interconnected reset signal network in some embodiments according to the present disclosure.

FIG. 13 is a diagram illustrating the structure of a voltage connecting pad in an array substrate in some embodiments according to the present disclosure.

FIG. 14 is a cross-sectional view along an F-F′ line in FIG. 3A.

### DETAILED DESCRIPTION

The disclosure will now be described more specifically with reference to the following embodiments. It is to be noted that the following descriptions of some embodiments are presented herein for purpose of illustration and description only. It is not intended to be exhaustive or to be limited to the precise form disclosed.

The present disclosure provides, inter alia, an array substrate and a display apparatus that substantially obviate one or more of the problems due to limitations and disadvantages of the related art. In one aspect, the present disclosure provides an array substrate. In some embodiments, the array substrate includes a plurality of pixel driving circuits, a plurality of first voltage supply lines, and a plurality of light emitting control signal lines. Optionally, a respective pixel driving circuit of the plurality of pixel driving circuits comprises a driving transistor, a first light emitting control transistor, a storage capacitor, and a voltage connecting pad. Optionally, the voltage connecting pad comprises a main portion and an extension portion extending away from the main portion. Optionally, the main portion connects a respective first voltage supply line of the plurality of first voltage supply lines with a second capacitor electrode of the storage capacitor. Optionally, the extension portion connects the main portion with a first electrode of the first light emitting control transistor. Optionally, the extension portion crosses over a respective light emitting control signal line of the plurality of light emitting control signal lines.

Various appropriate pixel driving circuits may be used in the present array substrate. Examples of appropriate driving circuits include 3TIC, 2T1C, 4TIC, 4T2C, 5T2C, 6T1C, 7T1C, 7T2C, 8TIC, and 8T2C. In some embodiments, the respective one of the plurality of pixel driving circuits is an 8TIC driving circuit. Various appropriate light emitting elements may be used in the present array substrate. Examples of appropriate light emitting elements include organic light emitting diodes, quantum dots light emitting diodes, and micro light emitting diodes. Optionally, the light emitting element is micro light emitting diode. Optionally, the light emitting element is an organic light emitting diode including an organic light emitting layer.

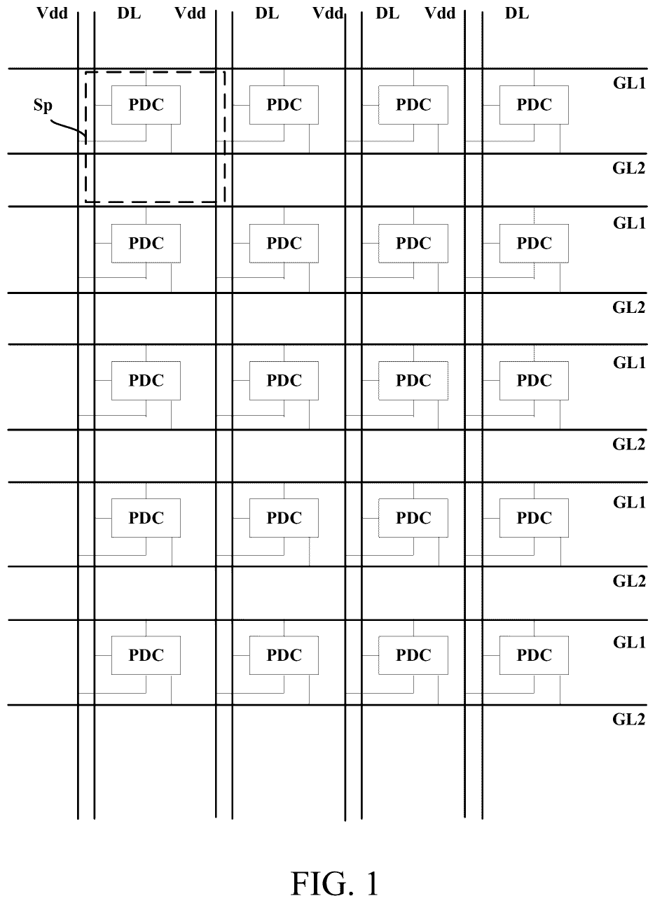

FIG. 1 is a plan view of an array substrate in some embodiments according to the present disclosure. Referring to FIG. 1, the array substrate includes an array of subpixels Sp. Each subpixel includes an electronic component, e.g., a light emitting element. In one example, the light emitting element is driven by a respective pixel driving circuit PDC. The array substrate includes a plurality of first gate lines GL1, a plurality of second gate lines GL2, a plurality of data lines DL, a plurality of first voltage supply line (e.g., a respective first voltage supply line Vdd), and a plurality of second voltage supply line (e.g., a respective second voltage supply line Vss). Light emission in a respective subpixel Sp is driven by a respective pixel driving circuit PDC. In one example, a high voltage signal (e.g., a VDD signal) is input, through the respective high voltage supply line Vdd, to the respective pixel driving circuit PDC connected to an anode of the light emitting element; a low voltage signal (e.g., a VSS signal) is input, through a low voltage supply line, to a cathode of the light emitting element. A voltage difference between the high voltage signal (e.g., the VDD signal) and the low voltage signal (e.g., the VSS signal) is a driving voltage ΔV that drives light emission in the light emitting element.

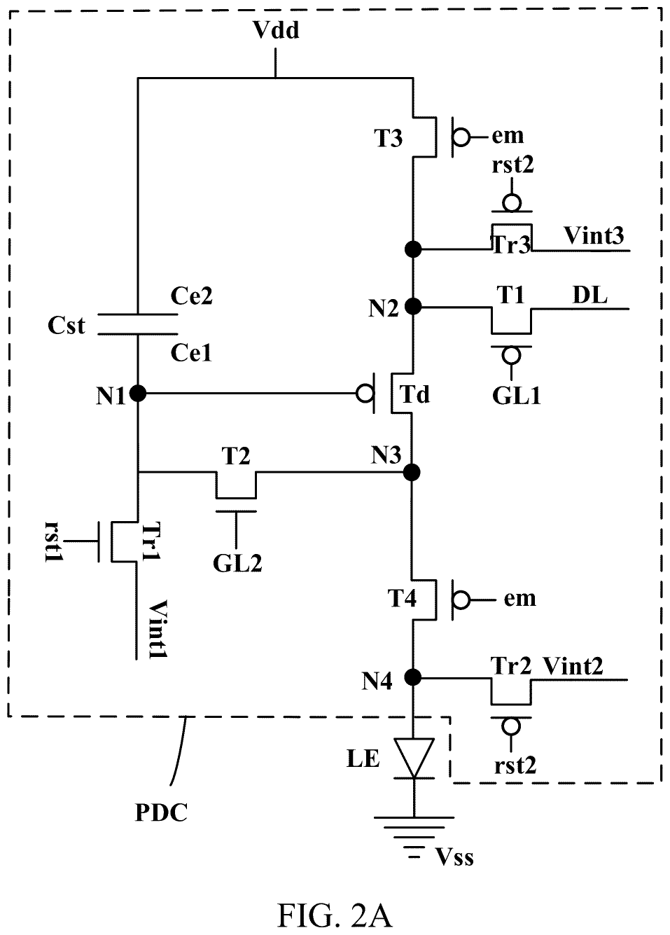

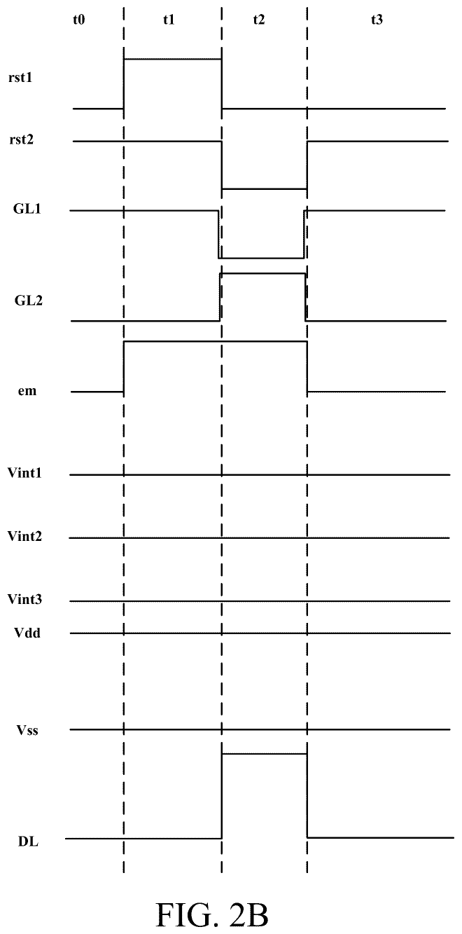

FIG. 2A is a circuit diagram illustrating the structure of a pixel driving circuit in some embodiments according to the present disclosure. Referring to FIG. 2A, in some embodiments, the pixel driving circuit includes a driving transistor Td; a storage capacitor Cst having a first capacitor electrode Ce1 and a second capacitor electrode Ce2; a first reset transistor Tr1 having a gate electrode connected to a respective first reset control signal line rst1 of a plurality of first reset control signal lines, a first electrode connected to a respective first reset signal line Vint1 of a plurality of first reset signal lines, and a second electrode connected to a first capacitor electrode Ce1 of the storage capacitor Cst and a gate electrode of the driving transistor Td; a second reset transistor Tr2 having a gate electrode connected to a respective second reset control signal line rst2 of a plurality of second reset control signal lines, a first electrode connected to a respective second reset signal line Vint2 of a plurality of second reset signal lines, and a second electrode connected to a second electrode of the fourth transistor T4 and an anode of the light emitting element LE; a third reset transistor Tr3 having a gate electrode connected to the respective second reset control signal line rst2 of the plurality of second reset control signal lines, a first electrode connected to a respective third reset signal line Vint3 of a plurality of third reset signal lines, and a second electrode connected to the first electrode of the driving transistor Td; a first transistor T1 (e.g., a data write transistor) having a gate electrode connected to a respective first gate line GL1 of a plurality of first gate lines, a first electrode connected to a respective data line DL of a plurality of data lines, and a second electrode connected to a first electrode of the driving transistor Td; a second transistor T2 (e.g., a compensating transistor) having a gate electrode connected to a respective second gate line GL2 of a plurality of second gate lines, a first electrode connected to the first capacitor electrode Ce1 of the storage capacitor Cst and the gate electrode of the driving transistor Td, and a second electrode connected to the second electrode of the driving transistor Td; a third transistor T3 having a gate electrode connected to a respective light emitting control signal line em of a plurality of light emitting control signal lines, a first electrode connected to a respective first voltage supply line Vdd of a plurality of first voltage supply lines, and a second electrode connected to the first electrode of the driving transistor Td and the second electrode of the first transistor T1; and a fourth transistor T4 having a gate electrode connected to the respective light emitting control signal line em of the plurality of light emitting control signal lines, a first electrode connected to second electrodes of the driving transistor Td and the second transistor T2, and a second electrode connected to an anode of a light emitting element LE and the second electrode of the second reset transistor Tr2. The second capacitor electrode Ce2 is connected to the respective voltage supply line and the first electrode of the third transistor T3.

In some embodiments, the pixel driving circuit includes a driving transistor Td, a data write transistor (e.g., the first transistor T1), a compensating transistor (e.g., the second transistor T2), two light emitting control transistors (e.g., the third transistor T3 and the fourth transistor T4), and three reset transistors (e.g., the first reset transistor Tr1, the second reset transistor Tr2, and the third reset transistor Tr3).

As used herein, a first electrode or a second electrode refers to one of a first terminal and a second terminal of a transistor, the first terminal and the second terminal being connected to an active layer of the transistor. A direction of a current flowing through the transistor may be configured to be from a first electrode to a second electrode, or from a second electrode to a first electrode. Accordingly, depending on the direction of the current flowing through the transistor, in one example, the first electrode is configured to receive an input signal and the second electrode is configured to output an output signal; in another example, the second electrode is configured to receive an input signal and the first electrode is configured to output an output signal.

The pixel driving circuit further include a first node N1, a second node N2, a third node N3, and a fourth node N4. The first node N1 is connected to the gate electrode of the driving transistor Td, the first capacitor electrode Ce1, the first electrode of the second transistor T2, and the second electrode of the first reset transistor Tr1. The second node N2 is connected to the second electrode of the third transistor T3, the second electrode of the first transistor T1, the second electrode of the third reset transistor Tr3, and the first electrode of the driving transistor Td. The third node N3 is connected to the second electrode of the driving transistor Td, the second electrode of the second transistor T2, and the first electrode of the fourth transistor T4. The fourth node N4 is connected to the second electrode of the fourth transistor T4, the second electrode of the second reset transistor Tr2, and the anode of the light emitting element LE.

The array substrate in some embodiments includes a plurality of subpixels. In some embodiments, the plurality of subpixels includes a respective first subpixel, a respective second subpixel, and a respective third subpixel. Optionally, a respective pixel of the array substrate includes the respective first subpixel, the respective second subpixel, and the respective third subpixel. The plurality of subpixels in the array substrate are arranged in an array. In one example, the array of the plurality of subpixels includes a S1-S2-S3 format repeating array, in which S1 stands for the respective first subpixel, S2 stands for the respective second subpixel, and S3 stands for the respective third subpixel. In another example, the S1-S2-S3 format is a C1-C2-C3 format, in which C1 stands for the respective first subpixel of a first color, C2 stands for the respective second subpixel of a second color, and C3 stands for the respective third subpixel of a third color. In another example, the C1-C2-C3 format is an R-G-B format, in which the respective first subpixel is a red subpixel, the respective second subpixel is a green subpixel, and the respective third subpixel is a blue subpixel.

In another example, the array of the plurality of subpixels includes a S1-S2-S3-S4 format repeating array, in which S1 stands for the respective first subpixel, S2 stands for the respective second subpixel, S3 stands for the respective third subpixel, and S4 stands for the respective fourth subpixel. In another example, the S1-S2-S3-S4 format is a C1-C2-C3-C4 format, in which C1 stands for the respective first subpixel of a first color, C2 stands for the respective second subpixel of a second color, C3 stands for the respective third subpixel of a third color, and C4 stands for the respective fourth subpixel of a fourth color. In another example, the S1-S2-S3-S4 format is a C1-C2-C3-C2′ format, in which C1 stands for the respective first subpixel of a first color, C2 stands for the respective second subpixel of a second color, C3 stands for the respective third subpixel of a third color, and C2′ stands for the respective fourth subpixel of the second color. In another example, the C1-C2-C3-C2′ format is a R-G-B-G format, in which the respective first subpixel is a red subpixel, the respective second subpixel is a green subpixel, the respective third subpixel is a blue subpixel, and the respective fourth subpixel is a green subpixel.

In some embodiments, a minimum repeating unit of the plurality of subpixels of the array substrate includes a respective first subpixel, a respective second subpixel, and a respective third subpixel. Optionally, each of the respective first subpixel, the respective second subpixel, and the respective third subpixel, includes the first transistor T1, the second transistor T2, the third transistor T3, the fourth transistor T4, the driving transistor Td, the first reset transistor Tr1, the second reset transistor Tr2, the third reset transistor Tr3, and the storage capacitor Cst.

In alternative embodiments, a minimum repeating unit of the plurality of subpixels of the array substrate includes a respective first subpixel, a respective second subpixel, a respective third subpixel, and a respective fourth subpixel. Optionally, each of the respective first subpixel, the respective second subpixel, the respective third subpixel, and the respective fourth subpixel includes the first transistor T1, the second transistor T2, the third transistor T3, the fourth transistor T4, the driving transistor Td, the first reset transistor Tr1, the second reset transistor Tr2, the third reset transistor Tr3, and the storage capacitor Cst.

The present disclosure may be implemented in pixel driving circuit having transistors of various types, including a pixel driving circuit having p-type transistors, a pixel driving circuit having n-type transistors, and a pixel driving circuit having one or more p-type transistors and one or more n-type transistors. Referring to FIG. 2A, the second transistor T2 and the first reset transistor are n-type transistors such as metal oxide transistors, and other transistors are p-type transistors such as polysilicon transistors. For a p-type transistor, an effective control signal (e.g., a turn-on control signal) is a low voltage signal, and an ineffective control signal (e.g., a turn-off control signal) is a high voltage signal. For an n-type transistor, an effective control signal (e.g., a turn-on control signal) is a high voltage signal, and an ineffective control signal (e.g., a turn-off control signal) is a low voltage signal.

FIG. 2B is a timing diagram illustrating the operation of a pixel driving circuit in some embodiments according to the present disclosure. Referring to FIG. 2A and FIG. 2B, during one frame of image, the operation of the pixel driving circuit includes a reset sub-phase t1, a data write sub-phase t2, and a light emitting sub-phase t3. In the initial sub-phase t0, a turning-off reset control signal is provided through the respective first reset control signal line rst1 to the gate electrode of the first reset transistor Tr1 to turn off the first reset transistor Tr1. A turning-off reset control signal is provided through the respective second reset control signal line rst2 to the gate electrode of the second reset transistor Tr2 and the gate electrode of the third reset transistor Tr3 to turn off the second reset transistor Tr2 and the third reset transistor Tr3. In the initial sub-phase t0, the respective first gate line GL1 and the respective second gate line GL2 are provided with a turning-off signal, thus the first transistor T1 and the second transistor T2 are turned off.

In the reset sub-phase t1, a turning-on reset control signal is provided through the first reset control signal line rst1 to the gate electrode of the first reset transistor Tr1 to turn on the first reset transistor Tr1; allowing an initialization voltage signal from the respective first reset signal line Vint1 to pass from a first electrode of the first reset transistor Tr1 to a second electrode of the first reset transistor Tr1, and in turn to the first capacitor electrode Ce1 and the gate electrode of the driving transistor Td. The gate electrode of the driving transistor Td is initialized. The second capacitor electrode Ce2 receives a high voltage signal from the respective first voltage supply line Vdd. The first capacitor electrode Ce1 is charged in the reset sub-phase t1 due to an increasing voltage difference between the first capacitor electrode Ce1 and the second capacitor electrode Ce2. In the reset sub-phase t1, the respective first gate line GL1 and the respective second gate line GL2 are provided with a turning-off signal, thus the first transistor T1 and the second transistor T2 are turned off. The respective light emitting control signal line em is provided with a high voltage signal to turn off the third transistor T3 and the fourth transistor T4.

In the data write sub-phase t2, the turning-off reset control signal is again provided through the respective first reset control signal line rst1 to the gate electrode of the first reset transistor Tr1 to turn off the first reset transistor Tr1. The respective first gate line GL1 and the respective second gate line GL2 are provided with turning-on signals, thus the first transistor T1 and the second transistor T2 are turned on. A second electrode of the driving transistor Td is connected with the second electrode of the second transistor T2. A gate electrode of the driving transistor Td is electrically connected with the first electrode of the second transistor T2. Because the second transistor T2 is turned on in the data write sub-phase t2, the gate electrode and the second electrode of the driving transistor Td are connected and short circuited, and only the PN junction between the gate electrode and a first electrode of the driving transistor Td is effective, thus rendering the driving transistor Td in a diode connecting mode. The first transistor T1 is turned on in the data write sub-phase t2. The data voltage signal transmitted through the respective data line DL is received by a first electrode of the first transistor T1, and in turn transmitted to the first electrode of the driving transistor Td, which is connected to the second electrode of the first transistor T1. A node N2 connecting to the first electrode of the driving transistor Td has a voltage level of the data voltage signal. Because only the PN junction between the gate electrode and a first electrode of the driving transistor Td is effective, the voltage level at the node N1 in the data write sub-phase t2 increase gradually to (Vdata+Vth), wherein the Vdata is the voltage level of the data voltage signal, and the Vth is the voltage level of the threshold voltage Th of the PN junction. The storage capacitor Cst is discharged because the voltage difference between the first capacitor electrode Ce1 and the second capacitor electrode Ce2 is reduced to a relatively small value. The respective light emitting control signal line em is provided with a high voltage signal to turn off the third transistor T3 and the fourth transistor T4.

In the data write sub-phase t2, a turning-on reset control signal is provided through the respective second reset control signal line rst2 to the gate electrode of the second reset transistor Tr2 to turn on the second reset transistor Tr2; allowing an initialization voltage signal from the respective second reset signal line Vint2 to pass from a first electrode of the second reset transistor Tr2 to a second electrode of the second reset transistor Tr2; and in turn to the node N4. The anode of the light emitting element LE is initialized. A turning-on reset control signal is provided through the respective second reset control signal line rst2 to the gate electrode of the third reset transistor Tr3 to turn on the third reset transistor Tr3; allowing an initialization voltage signal from the respective second reset signal line Vint2 to pass from a first electrode of the third reset transistor Tr3 to a second electrode of the third reset transistor Tr3; and in turn to the node N2. The node N2 is initialized.

In the light emitting sub-phase t3, the turning-off reset control signal is again provided through the respective first reset control signal line rst1 to the gate electrode of the first reset transistor Tr1 to turn off the first reset transistor Tr1. The respective first gate line GL1 and the respective second gate line GL2 are provided with a turning-off signal, the first transistor T1 and the second transistor T2 are turned off. The respective light emitting control signal line em is provided with a low voltage signal to turn on the third transistor T3 and the fourth transistor T4. The voltage level at the node N1 in the light emitting sub-phase t3 is maintained at (Vdata+Vth), the driving transistor Td is turned on by the voltage level, and working in the saturation area. A path is formed through the third transistor T3, the driving transistor Td, the fourth transistor T4, to the light emitting element LE. The driving transistor Td generates a driving current for driving the light emitting element LE to emit light. A voltage level at a node N3 connected to the second electrode of the driving transistor Td equals to a light emitting voltage of the light emitting element LE.

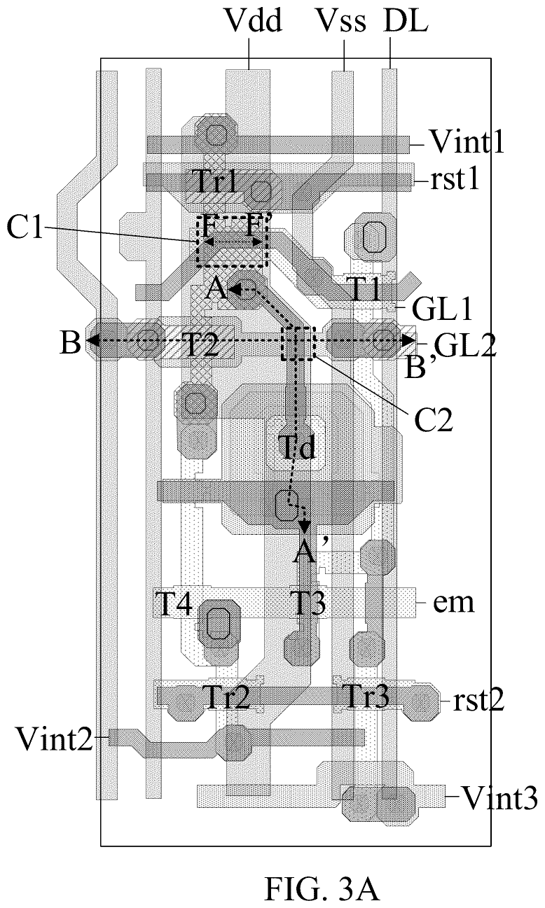

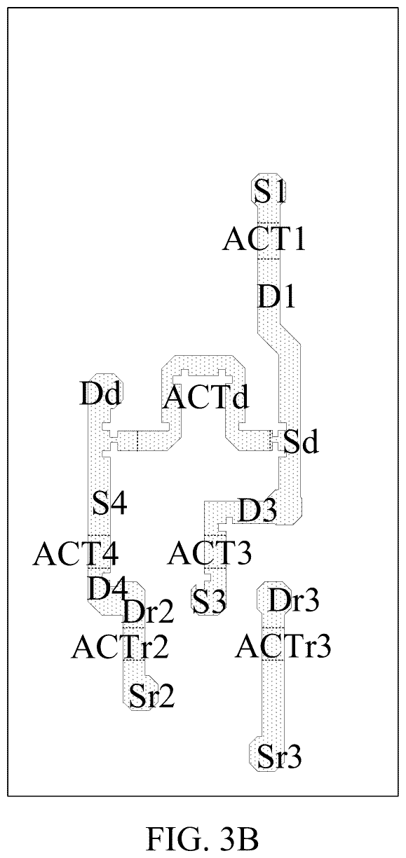

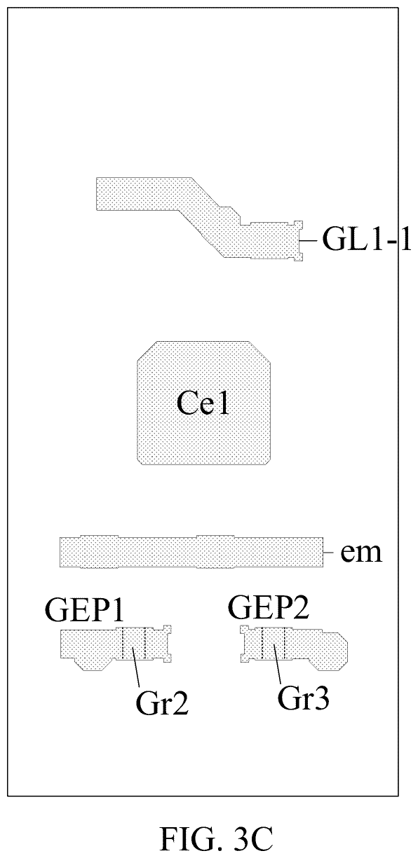

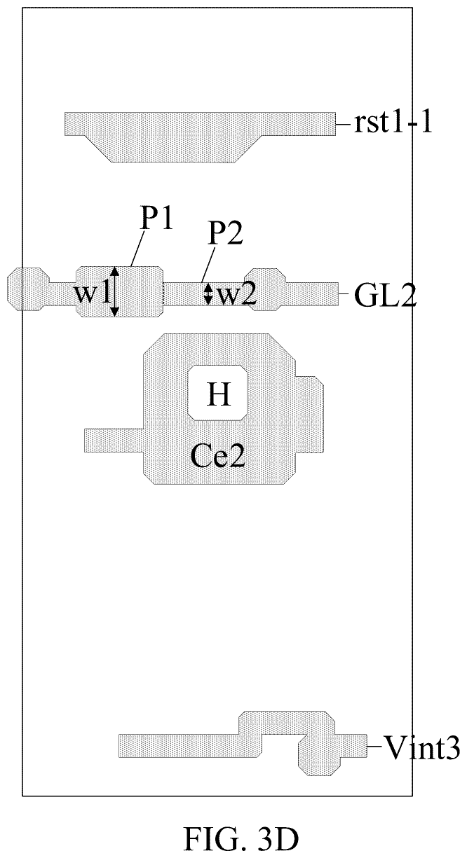

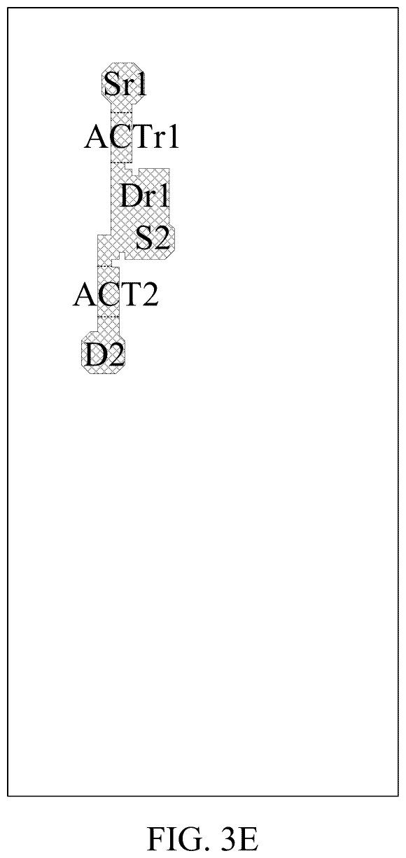

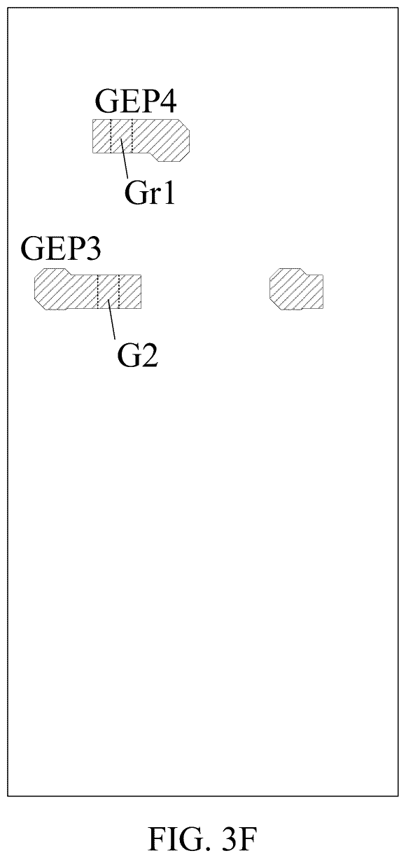

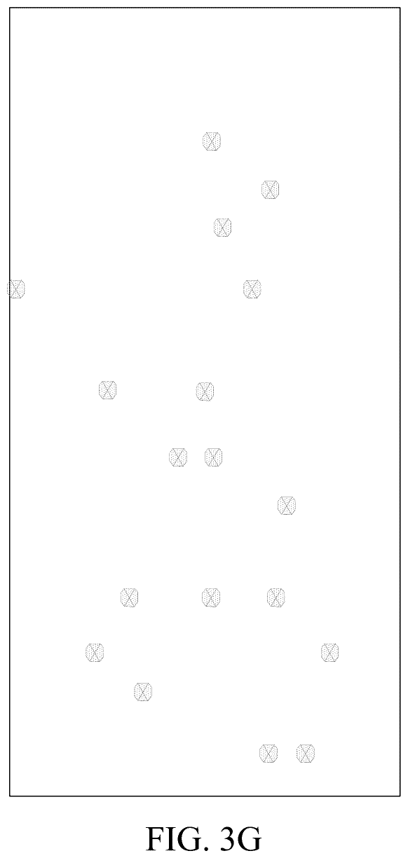

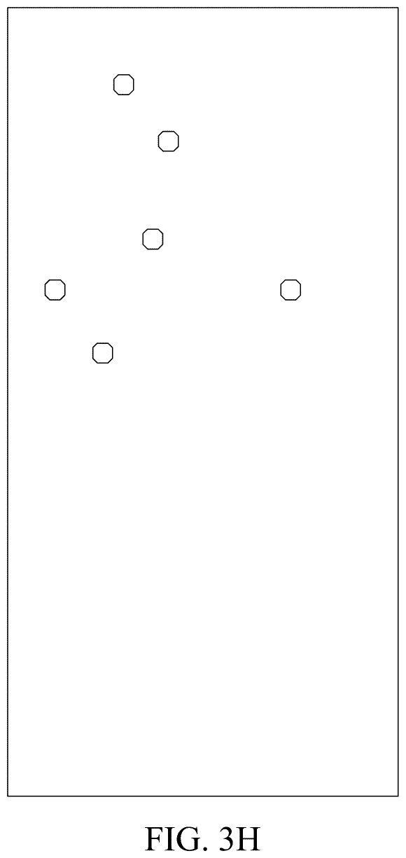

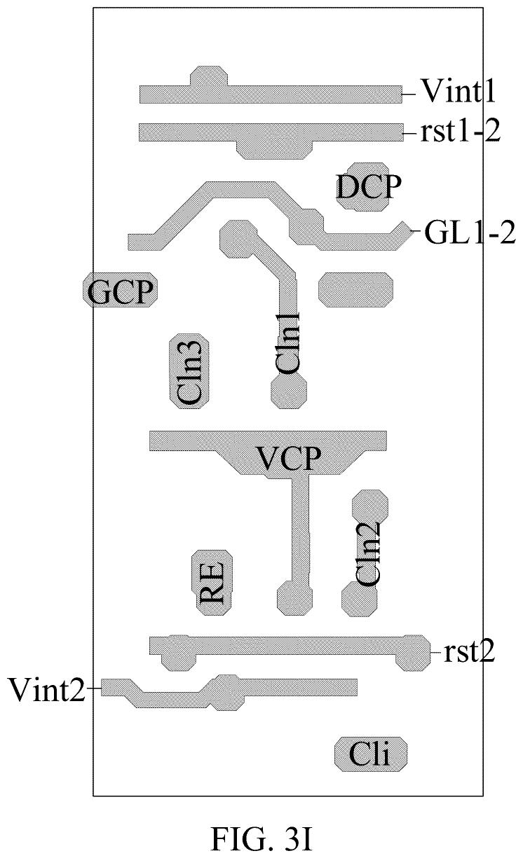

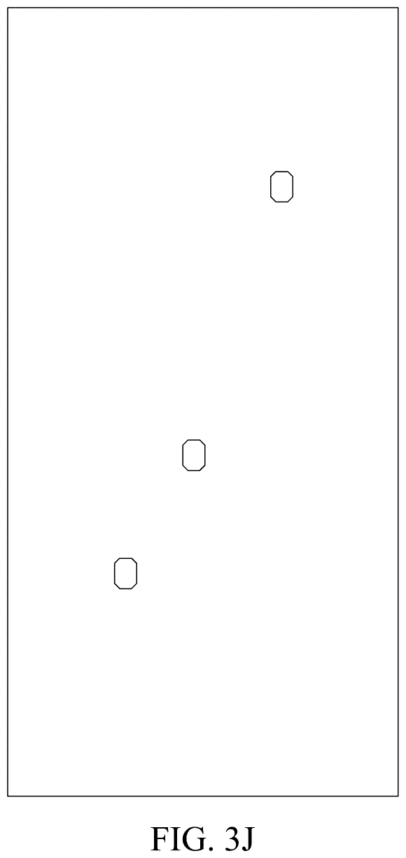

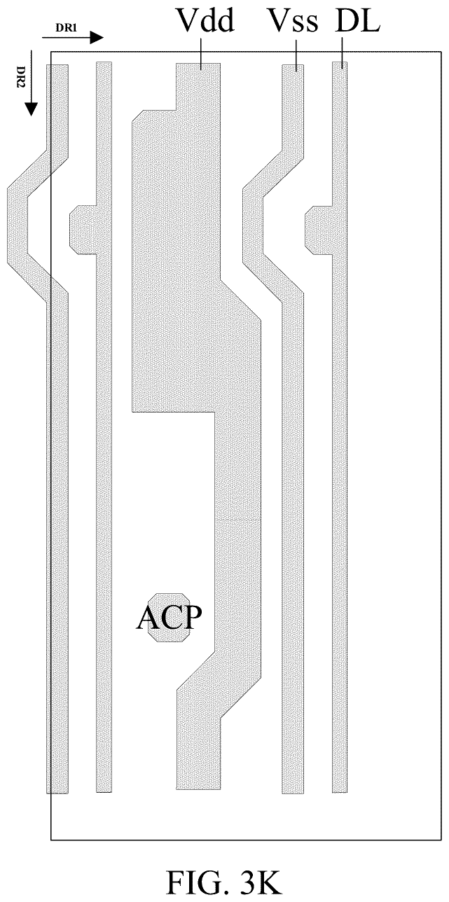

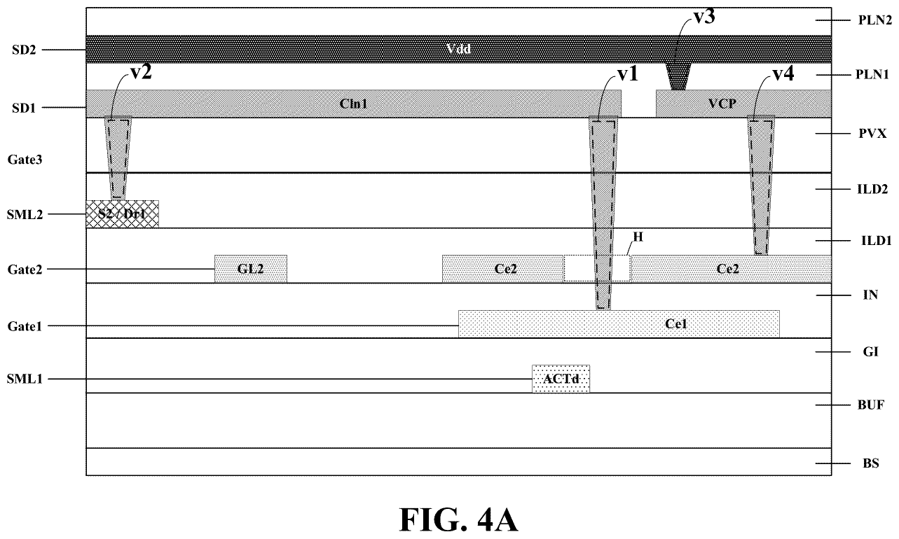

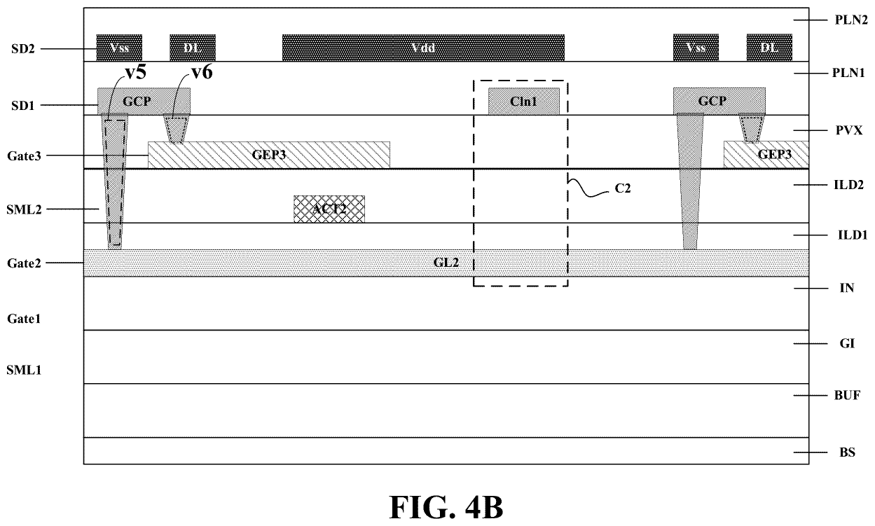

FIG. 3A is a diagram illustrating the structure of a pixel driving circuit in an array substrate in some embodiments according to the present disclosure. FIG. 3B is a diagram illustrating the structure of a first semiconductor material layer in the array substrate depicted in FIG. 3A. FIG. 3C is a diagram illustrating the structure of a first gate metal layer in the array substrate depicted in FIG. 3A. FIG. 3D is a diagram illustrating the structure of a second gate metal layer in the array substrate depicted in FIG. 3A. FIG. 3E is a diagram illustrating the structure of a second semiconductor material layer in the array substrate depicted in FIG. 3A. FIG. 3F is a diagram illustrating the structure of a third gate metal layer in the array substrate depicted in FIG. 3A. FIG. 3G is a diagram illustrating vias extending through a first inter-layer dielectric layer in the array substrate depicted in FIG. 3A. FIG. 3H is a diagram illustrating vias extending through a passivation layer in the array substrate depicted in FIG. 3A. FIG. 3I is a diagram illustrating the structure of a first signal line layer in the array substrate depicted in FIG. 3A. FIG. 3J is a diagram illustrating vias extending through a first planarization layer in the array substrate depicted in FIG. 3A. FIG. 3K is a diagram illustrating the structure of a second signal line layer in the array substrate depicted in FIG. 3A. FIG. 4A is a cross-sectional view along an A-A′ line in FIG. 3A. FIG. 4B is a cross-sectional view along a B-B′ line in FIG. 3A.

Referring to FIG. 3A to FIG. 3K, and FIG. 4A to FIG. 4B, the array substrate in some embodiments includes a base substrate BS, a buffer layer BUF on the base substrate BS, a first semiconductor material layer SML1 on a side of the buffer layer BUF away from the base substrate BS, a gate insulating layer G1 on a side of the first semiconductor material layer SML1 away from the base substrate BS, a first gate metal layer Gate1 on a side of the gate insulating layer G1 away from the first semiconductor material layer SML1, an insulating layer IN on a side of the first gate metal layer Gate1 away from the gate insulating layer G1, a second gate metal layer Gate2 on a side of the insulating layer IN away from the first gate metal layer Gate1, a first inter-layer dielectric layer ILD1 on a side of the second gate metal layer Gate2 away from the insulating layer IN, a second semiconductor material layer SML2 on a side of the first inter-layer dielectric layer ILD1 away from the second gate metal layer Gate2, a second inter-layer dielectric layer ILD2 on a side of the second semiconductor material layer SML2 away from the first inter-layer dielectric layer ILD1, a third gate metal layer Gate3 on a side of the second inter-layer dielectric layer ILD2 away from the second semiconductor material layer SML2, a passivation layer PVX on a side of the third gate metal layer Gate3 away from the second inter-layer dielectric layer ILD2, a first signal line layer SD1 on a side of the passivation layer PVX away from the third gate metal layer Gate3, a first planarization layer PLN1 on a side of the first signal line layer SD1 away from the passivation layer PVX, a second signal line layer SD2 on a side of the first planarization layer PLN1 away from the first signal line layer SD1, and a second planarization layer PLN2 on a side of the second signal line layer SD2 away from the first planarization layer PLN1.

Referring to FIG. 2A, FIG. 3A, FIG. 3B, FIG. 4A, and FIG. 4B, the first semiconductor material layer SML1 in some embodiments includes at least active layers of multiple transistors of the pixel driving circuit, including the first transistor T1, the third transistor T3, the fourth transistor T4, the second reset transistor Tr2, the third reset transistor Tr3, and the driving transistor Td. Optionally, the first semiconductor material layer SML1 further includes at least respective portions of first electrodes of multiple transistors of the pixel driving circuit, including the first transistor T1, the third transistor T3, the fourth transistor T4, the second reset transistor Tr2, the third reset transistor Tr3, and the driving transistor Td. Optionally, the first semiconductor material layer SML1 further includes at least respective portions of second electrodes of multiple transistors of the pixel driving circuit, including the first transistor T1, the third transistor T3, the fourth transistor T4, the second reset transistor Tr2, the third reset transistor Tr3, and the driving transistor Td. Optionally, the first semiconductor material layer SML1 includes active layers, first electrodes, and second electrodes of multiple transistors of the pixel driving circuit, including the first transistor T1, the third transistor T3, the fourth transistor T4, the second reset transistor Tr2, the third reset transistor Tr3, and the driving transistor Td. Various appropriate semiconductor materials may be used for making the first semiconductor material layer SML1. Examples of the semiconductor materials for making the first semiconductor material layer SML1 include silicon-based semiconductor materials such as polycrystalline silicon, single-crystal silicon, and amorphous silicon.

FIG. 3B is annotated with labels indicating components of each of multiple transistors (T1, T3, T4, Tr2, Tr3, and Td) in the pixel driving circuit. For example, the first transistor T1 includes an active layer ACT1, a first electrode S1, and a second electrode D1. The third transistor T3 includes an active layer ACT3, a first electrode S3, and a second electrode D3. The fourth transistor T4 includes an active layer ACT4, a first electrode S4, and a second electrode D4. The second reset transistor Tr2 includes an active layer ACTr2, a first electrode Sr2, and a second electrode Dr2. The third reset transistor Tr3 includes an active layer ACTr3, a first electrode Sr3, and a second electrode Dr3. The driving transistor Td includes an active layer ACTd, a first electrode Sd, and a second electrode Dd.

Optionally, the active layers (ACT1, ACT3, ACT4, ACTr2, ACTr3, and ACTd), the first electrodes (S1, S3, S4, Sr2, Sr3, and Sd), and the second electrodes (D1, D3, D4, Dr2, Dr3, and Dd) of the respective transistors (T1, T3, T4, Tr2, Tr3, and Td) are in a same layer.

In some embodiments, the active layers (ACT1, ACT3, ACT4, ACTr2, and ACTd), at least portions of the first electrodes (S1, S3, S4, Sr2, and Sd), and at least portions of the second electrodes (D1, D3, D4, Dr2, and Dd) of multiple transistors (T1, T3, T4, Tr2, and Td) in the pixel driving circuit are parts of a unitary structure. Optionally, a part of the third reset transistor Tr3 (ACTr3, Sr3, Dr3) in the first semiconductor material layer is spaced apart from the unitary structure (T1, T3, T4, Tr2, and Td) in a same pixel driving circuit.

Referring to FIG. 2A, FIG. 3A, FIG. 3C, FIG. 4A, and FIG. 4B, the first gate metal layer Gate1 in some embodiments includes at least portions of a plurality of first gate lines (e.g., a respective first gate line first branch GL1-1), a plurality of light emitting control signal lines (e.g., a respective light emitting control signal line em), a first gate electrode pad GEP1, a second gate electrode pad GEP2, and a first capacitor electrode Ce1 of the storage capacitor Cst.

In some embodiments, a respective first gate line includes multiple branches respectively in multiple layers. In one example, the respective first gate line includes a respective first gate line first branch GL1-1 in the first gate metal layer Gate1 (as shown in FIG. 3C) and a respective first gate line second branch GL1-2 in the first signal line layer SD1 (as shown in FIG. 3I). Optionally, an orthographic projection of the respective first gate line first branch GL1-1 on a base substrate BS at least partially (e.g., at least 80%, at least 85%, at least 90%, at least 95%, at least 98%, or at least 99%) overlaps with an orthographic projection of the respective first gate line second branch GL1-2 on the base substrate BS.

Various appropriate electrode materials and various appropriate fabricating methods may be used to make the first gate metal layer Gate1. For example, a conductive material may be deposited on the substrate by a plasma-enhanced chemical vapor deposition (PECVD) process and patterned. Examples of appropriate conductive materials for making the first gate metal layer Gate1 include, but are not limited to, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. Optionally, the at least portions of the plurality of first gate lines (e.g., the respective first gate line first branch GL1-1), the plurality of light emitting control signal lines (e.g., the respective light emitting control signal line em), the first gate electrode pad GEP1, the second gate electrode pad GEP2, and the first capacitor electrode Ce1 of the storage capacitor Cst are in a same layer.

As used herein, the term “same layer” refers to the relationship between the layers simultaneously formed in the same step. In one example, the plurality of light emitting control signal lines and the first capacitor electrode Ce1 are in a same layer when they are formed as a result of one or more steps of a same patterning process performed in a same layer of material. In another example, the plurality of light emitting control signal lines and the first capacitor electrode Ce1 can be formed in a same layer by simultaneously performing the step of forming the plurality of light emitting control signal lines, and the step of forming the first capacitor electrode Ce1. The term “same layer” does not always mean that the thickness of the layer or the height of the layer in a cross-sectional view is the same.

In some embodiments, the first gate electrode pad GEP1 includes the gate electrode Gr2 of the second reset transistor Tr2 in the pixel driving circuit. In some embodiments, the second gate electrode pad GEP2 includes the gate electrode Gr3 of the third reset transistor Tr3 in the pixel driving circuit. The first gate electrode pad GEP1 and the second gate electrode pad GEP2 are connected to a respective second reset control signal line rst2 of a plurality of second reset control signal lines, respectively.

Referring to FIG. 2A, FIG. 3A, FIG. 3D, FIG. 4A, and FIG. 4B, the second gate metal layer Gate2 in some embodiments includes at least portions of a plurality of first reset control signal lines (e.g., a respective first reset control signal line first branch rst1-1), a plurality of second gate lines (e.g., a respective second gate line GL2), a plurality of third reset signal lines (e.g., a respective third reset signal line Vint3), and a second capacitor electrode Ce2 of the storage capacitor Cst. Various appropriate electrode materials and various appropriate fabricating methods may be used to make the second gate metal layer Gate2. For example, a conductive material may be deposited on the substrate by a plasma-enhanced chemical vapor deposition (PECVD) process and patterned. Examples of appropriate conductive materials for making the second gate metal layer Gate2 include, but are not limited to, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. Optionally, the at least portions of the plurality of first reset control signal lines (e.g., the respective first reset control signal line first branch rst1-1), the plurality of second gate lines (e.g., the respective second gate line GL2), the plurality of third reset signal lines (e.g., the respective third reset signal line Vint3), and the second capacitor electrode Ce2 of the storage capacitor Cst are in a same layer.

In some embodiments, a respective first reset control signal line includes multiple branches respectively in multiple layers. In one example, the respective first reset control signal line includes a respective first reset control signal line first branch rst1-1 in the second gate metal layer Gate2 (as shown in FIG. 3D) and a respective first reset control signal line second branch rst1-2 in the first signal line layer SD1 (as shown in FIG. 3I). Optionally, an orthographic projection of the respective first reset control signal line first branch rst1-1 on a base substrate BS at least partially (e.g., at least 80%, at least 85%, at least 90%, at least 95%, at least 98%, or at least 99%) overlaps with an orthographic projection of the respective first reset control signal line second branch rst1-2 on the base substrate BS.

Referring to FIG. 2A, FIG. 3A, FIG. 3E, FIG. 4A, and FIG. 4B, the second semiconductor material layer SML2 in some embodiments includes at least an active layer ACT2 of the second transistor T2 and an active layer ACTr1 of the first reset transistor Tr1. Optionally, the second semiconductor material layer SML2 further includes at least a portion of a first electrode S2 of the second transistor T2 and at least a portion of a first electrode Sr1 of the first reset transistor Tr1. Optionally, the second semiconductor material layer SML2 further includes at least a portion of a second electrode D2 of the second transistor T2 and at least a portion of a second electrode Dr1 of the first reset transistor Tr1. Optionally, the second semiconductor material layer SML2 includes the active layer ACT2, the first electrode S2, and the second electrode D2 of the second transistor T2; and the active layer ACTr1, the first electrode Sr1, and the second electrode Dr1 of the first reset transistor Tr1. In the present array substrate, at least the active layer ACT2 of the second transistor T2 and the active layer ACTr1 of the first reset transistor Tr1 are in a layer different from at least the active layers of other transistors. Various appropriate semiconductor materials may be used for making the second semiconductor material layer SML2. Examples of the semiconductor materials for making the second semiconductor material layer SML2 include metal oxide-based semiconductor material such as indium gallium zinc oxide and metal oxynitride-based semiconductor materials such as zinc oxynitride.

FIG. 3E is annotated with labels indicating components of the second transistor T2 and the first reset transistor Tr1. For example, the second transistor T2 includes an active layer ACT2, a first electrode S2, and a second electrode D2; and the first reset transistor Tr1 includes an active layer ACTr1, a first electrode Sr1, and a second electrode Dr1. Optionally, the active layer ACT2, the first electrode S2, the second electrode D2 of the second transistor T2; and the active layer ACTr1, the first electrode Sr1, and the second electrode Dr1 of the first reset transistor Tr1 are in a same layer. Optionally, the active layer ACT2 of the second transistor T2 and the active layer ACTr1 of the first reset transistor Tr1 are parts of a unitary structure. Optionally, the active layer ACT2, the first electrode S2, the second electrode D2 of the second transistor T2; and the active layer ACTr1, the first electrode Sr1, and the second electrode Dr1 of the first reset transistor Tr1 are parts of a unitary structure.

Referring to FIG. 2A, FIG. 3A, FIG. 3F, FIG. 4A, and FIG. 4B, the third gate metal layer Gate3 in some embodiments includes a third gate electrode pad GEP3 and a fourth gate electrode pad GEP4. Various appropriate electrode materials and various appropriate fabricating methods may be used to make the third gate metal layer Gate3. For example, a conductive material may be deposited on the substrate by a plasma-enhanced chemical vapor deposition (PECVD) process and patterned. Examples of appropriate conductive materials for making the third gate metal layer Gate3 include, but are not limited to, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. Optionally, the third gate electrode pad GEP3 and the fourth gate electrode pad GEP4 are in a same layer.

In some embodiments, the third gate electrode pad GEP3 includes the gate electrode G2 of the second transistor T2 in the pixel driving circuit. In some embodiments, the fourth gate electrode pad GEP4 includes the gate electrode Gr1 of the first reset transistor Tr1 in the pixel driving circuit. The third gate electrode pad GEP3 is connected to a respective second gate line GL2 of a plurality of second gate lines through a gate connecting pad (“GCP” in FIG. 3I). The fourth gate electrode pad GEP4 is connected to a respective first reset control signal line rst1 of a plurality of first reset control signal lines. In one example, the fourth gate electrode pad GEP4 is connected to a respective first reset control signal line second branch (“rst1-2” in FIG. 3I).

Vias extending through the first inter-layer dielectric layer ILD1 are depicted in FIG. 3G.

Vias extending through the passivation layer PVX are depicted in FIG. 3H.

Referring to FIG. 2A, FIG. 3A, FIG. 3I, FIG. 4A, and FIG. 4B, the first signal line layer SD1 in some embodiments includes a plurality of first reset signal lines (e.g., a respective first reset signal line Vint1); a plurality of second reset signal lines (e.g., a respective second reset signal line Vint2); at least portions of a plurality of first reset control signal lines (e.g., a respective first reset control signal line second branch rst1-2), at least portions of a plurality of first gate lines (e.g., a respective first gate line second branch GL1-2), a plurality of second reset control signal lines (e.g., a respective second reset control signal line rst2); a gate connecting pad GCP; a relay electrode RE; a first node connecting line Cln1; a second node connecting line Cln2; a third node connecting line Cln3; a voltage connecting pad VCP; a data signal connecting pad DCP; and a reset signal connecting pad Cli.

Various appropriate conductive materials and various appropriate fabricating methods may be used to make the first signal line layer SD1. For example, a conductive material may be deposited on the substrate by a plasma-enhanced chemical vapor deposition (PECVD) process and patterned. Examples of appropriate conductive materials for making the first signal line layer include, but are not limited to, titanium, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. In some embodiments, the first signal line layer includes a plurality of sub-layers stacked together. In one example, the first signal line layer includes a stacked titanium/aluminum/titanium multi-layer structure. In another example, the first signal line layer includes a stacked molybdenum/aluminum/molybdenum multi-layer structure.

Optionally, the plurality of first reset signal lines (e.g., the respective first reset signal line Vint1); the plurality of second reset signal lines (e.g., the respective second reset signal line Vint2); at least portions of the plurality of first reset control signal lines (e.g., the respective first reset control signal line second branch rst1-2), at least portions of the plurality of first gate lines (e.g., the respective first gate line second branch GL1-2), the plurality of second reset control signal lines (e.g., the respective second reset control signal line rst2); the gate connecting pad GCP; the relay electrode RE; the first node connecting line Cln1; the second node connecting line Cln2; the third node connecting line Cln3; the voltage connecting pad VCP; the data signal connecting pad DCP; and the reset signal connecting pad Cli are in a same layer.

In some embodiments, the first node connecting line Cln1 in the pixel driving circuit connects multiple components of the pixel driving circuit to the node N1. Referring to FIG. 4A, the first node connecting line Cln1 is connected to the first capacitor electrode Ce1 through a first via v1, and connected to the second transistor T2 (e.g., to the first electrode S2 of the second transistor T2) through a second via v2. Optionally, the first node connecting line Cln1 corresponds to the node N1 depicted in FIG. 2A.

Referring to FIG. 2A, FIG. 3A, FIG. 3C, FIG. 3D, and FIG. 4A, in some embodiments, in a hole region H, a portion of the second capacitor electrode Ce2 is absent. Optionally, an orthographic projection of the second capacitor electrode Ce2 on a base substrate BS substantially (e.g., at least 80%, at least 85%, at least 90%, at least 95%, at least 98%, at least 99%, or 100%) covers, with a margin, an orthographic projection of the first capacitor electrode Ce1 on the base substrate BS except for the hole region H in which a portion of the second capacitor electrode Ce2 is absent. Optionally, the first via v1 extends through the passivation layer PVX, the second inter-layer dielectric layer ILD2, the first inter-layer dielectric layer ILD1, the hole region H, and the insulating layer IN.

In some embodiments, the first node connecting line Cln1 crosses over a respective second gate line GL2 of the plurality of second gate lines. As shown in FIG. 3A, FIG. 3D, and FIG. 4A, the first node connecting line Cln1 crosses over the respective second gate line in the second gate metal layer Gate2. An orthographic projection of the first node connecting line Cln1 on a base substrate at least partially overlaps with an orthographic projection of the respective second gate line on the base substrate.

Referring to FIG. 3A, FIG. 3I, FIG. 3K, and FIG. 4A, the data signal connecting pad DCP in the pixel driving circuit connects the respective data line DL to the first electrode S1 of the first transistor T1, data signals provided by the respective data line DL is transmitted to the first electrode S1 of the first transistor T1 through the signal connecting pad DCP.

In some embodiments, a respective first gate line includes multiple branches respectively in multiple layers. In one example, the respective first gate line includes a respective first gate line first branch GL1-1 in the first gate metal layer Gate1 (as shown in FIG. 3C) and a respective first gate line second branch GL1-2 in the first signal line layer SD1 (as shown in FIG. 3I). Optionally, an orthographic projection of the respective first gate line first branch GL1-1 on a base substrate BS at least partially (e.g., at least 80%, at least 85%, at least 90%, at least 95%, at least 98%, or at least 99%) overlaps with an orthographic projection of the respective first gate line second branch GL1-2 on the base substrate BS.

In some embodiments, a respective first reset control signal line includes multiple branches respectively in multiple layers. In one example, the respective first reset control signal line includes a respective first reset control signal line first branch rst1-1 in the second gate metal layer Gate2 (as shown in FIG. 3D) and a respective first reset control signal line second branch rst1-2 in the first signal line layer SD1 (as shown in FIG. 3I). Optionally, an orthographic projection of the respective first reset control signal line first branch rst1-1 on a base substrate BS at least partially (e.g., at least 80%, at least 85%, at least 90%, at least 95%, at least 98%, or at least 99%) overlaps with an orthographic projection of the respective first reset control signal line second branch rst1-2 on the base substrate BS.

Referring to FIG. 3A, FIG. 3D, FIG. 3F, FIG. 3I, FIG. 4A, and FIG. 4B, the gate connecting pad GCP connects the third gate electrode pad GEP3 in the third gate metal layer Gate3 to a respective second gate line GL2 of a plurality of second gate lines in the second gate metal layer Gate2. Gate scanning signals provided by the respective second gate line GL2 is transmitted to the gate electrode G2 of the second transistor T2 through the gate connecting pad GCP. Referring to FIG. 4B, the gate connecting pad GCP is connected to the respective second gate line GL2 through a fifth via v5, and is connected to the third gate electrode pad GEP3 through a sixth via v6. In one example, the fifth via v5 extends through the passivation layer PVX, the second inter-layer dielectric layer ILD2, and the first inter-layer dielectric layer ILD1. In another example, the sixth via v6 extends through the passivation layer PVX.

Referring to FIG. 3A, FIG. 3D, FIG. 3I, FIG. 3K, FIG. 4A, and FIG. 4B, the voltage connecting pad VCP connects a respective first voltage supply line Vdd with the second capacitor electrode Ce2 of the storage capacitor. Referring to FIG. 4A, the respective first voltage supply line Vdd is connected to the voltage connecting pad VCP through a third via v3. The voltage connecting pad VCP is connected to the second capacitor electrode Ce2 of the storage capacitor through a fourth via v4. In one example, the third via v3 extends through the first planarization layer PLN1. In another example, the fourth via v4 extends through the passivation layer PVX, the second inter-layer dielectric layer ILD2, and the first inter-layer dielectric layer ILD1.

Referring to FIG. 3A, FIG. 3B, FIG. 3I, FIG. 3K, FIG. 4A, and FIG. 4B, the relay electrode RE connects an anode connecting pad ACP with a second electrode D4 of the fourth transistor T4 in the pixel driving circuit. The anode connecting pad ACP is further connected to an anode of a light emitting element.

Referring to FIG. 3A, FIG. 3B, FIG. 3D, FIG. 3I, FIG. 4A, and FIG. 4B, the reset signal connecting line Cli connects the respective third reset signal line Vint3 with the first electrode Sr3 of the third reset transistor Tr3 in the pixel driving circuit, thereby providing a reset signal to the first electrode Sr3 of the third reset transistor Tr3 in the pixel driving circuit.

Referring to FIG. 3A, FIG. 3B, FIG. 3I, FIG. 4A, and FIG. 4B, the second node connecting line Cln2 in the pixel driving circuit is connected to a second electrode D3 of the third transistor T3 in the pixel driving circuit, and connected to a second electrode Dr3 of the third reset transistor Tr3 in the pixel driving circuit.

Referring to FIG. 3A, FIG. 3B, FIG. 3I, FIG. 4A, and FIG. 4B, the third node connecting line Cln3 in the pixel driving circuit is connected to a second electrode D2 of the second transistor T2 in the pixel driving circuit, and connected to a second electrode Dd of the driving transistor Td and a first electrode S4 of the fourth transistor T4 in the pixel driving circuit.

Vias extending through the first planarization layer PLN1 are depicted in FIG. 3J.

Referring to FIG. 2A, FIG. 3A, FIG. 3K, FIG. 4A, and FIG. 4B, the second signal line layer SD2 in some embodiments includes a plurality of first voltage supply lines (e.g., a respective first voltage supply line Vdd), a plurality of second voltage supply lines (e.g., a respective second voltage supply line Vss), a plurality of data lines (e.g., a respective data line DL), and an anode contact pad ACP. Various appropriate conductive materials and various appropriate fabricating methods may be used to make the second signal line layer SD2. For example, a conductive material may be deposited on the substrate by a plasma-enhanced chemical vapor deposition (PECVD) process and patterned. Examples of appropriate conductive materials for making the second signal line layer SD2 include, but are not limited to, titanium, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. In some embodiments, the second signal line layer includes a plurality of sub-layers stacked together. In one example, the second signal line layer includes a stacked titanium/aluminum/titanium multi-layer structure. In another example, the second signal line layer includes a stacked molybdenum/aluminum/molybdenum multi-layer structure. Optionally, the plurality of first voltage supply lines (e.g., the respective first voltage supply line Vdd), the plurality of second voltage supply lines (e.g., the respective second voltage supply line Vss), the plurality of data lines (e.g., the respective data line DL), and the anode contact pad ACP are in a same layer.

In some embodiments, the plurality of first voltage supply lines are configured to provide a first reference voltage signal. Optionally, the plurality of second voltage supply lines are configured to provide a second reference voltage signal. Optionally, the second reference voltage signal being different from the first reference voltage signal. In one example, the first reference voltage signal is a constant voltage signal, e.g., a high reference voltage signal. In another example, the second reference voltage signal is a constant voltage signal, e.g., a low reference voltage signal.

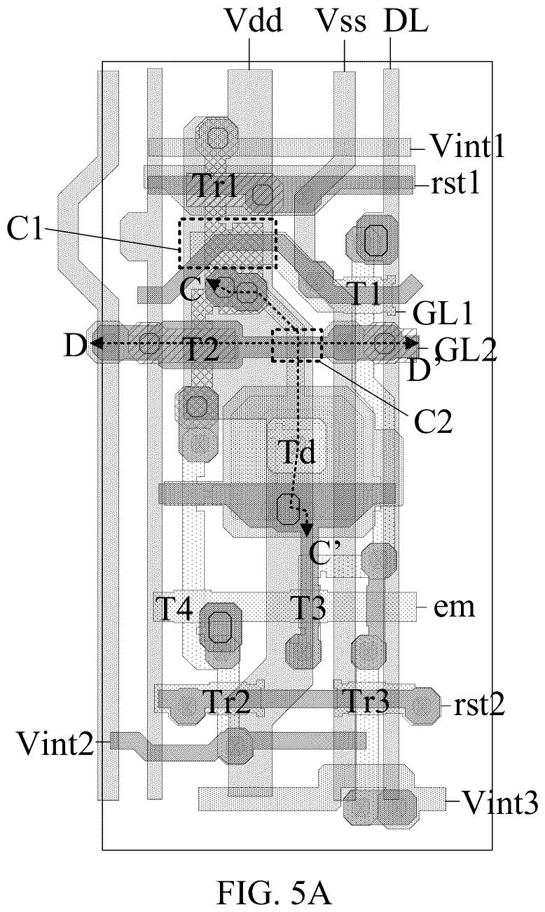

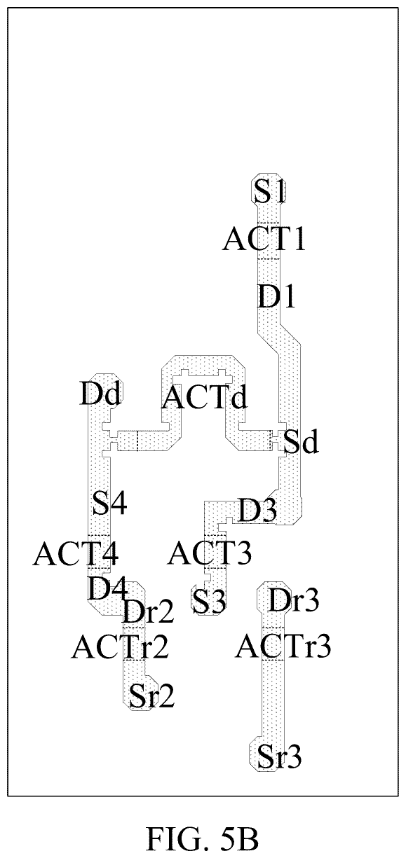

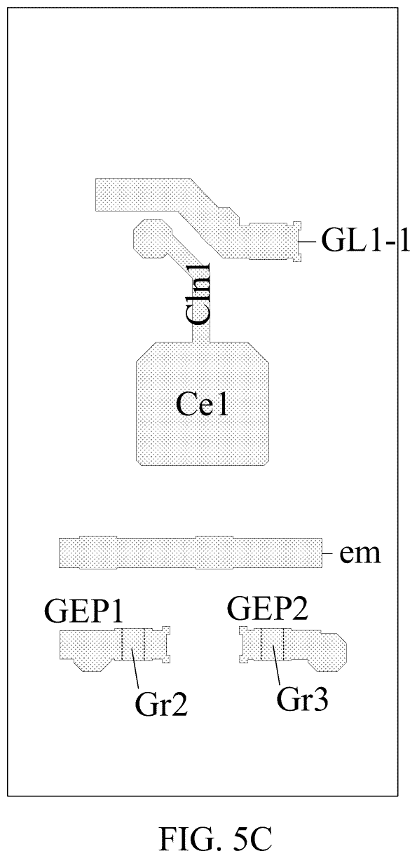

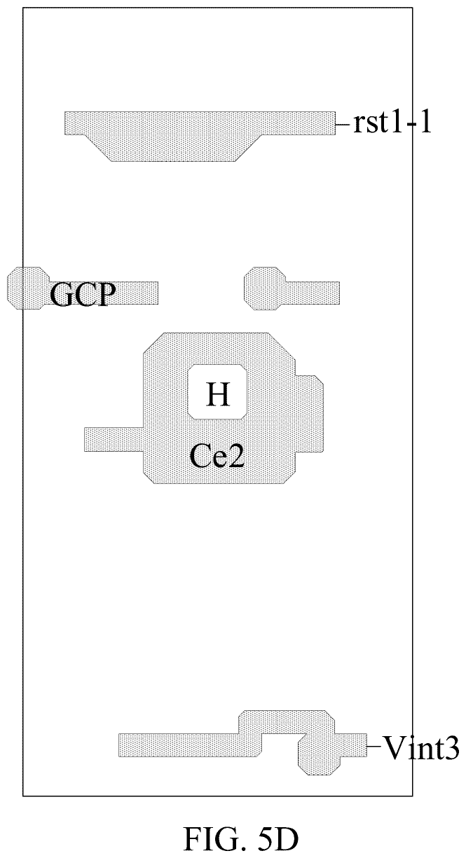

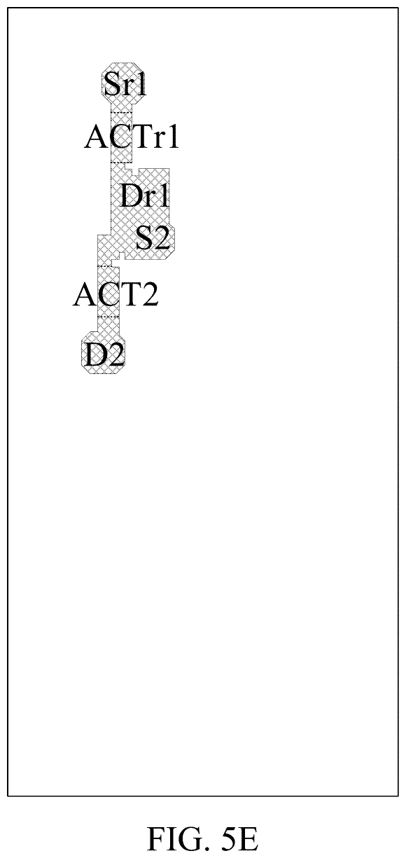

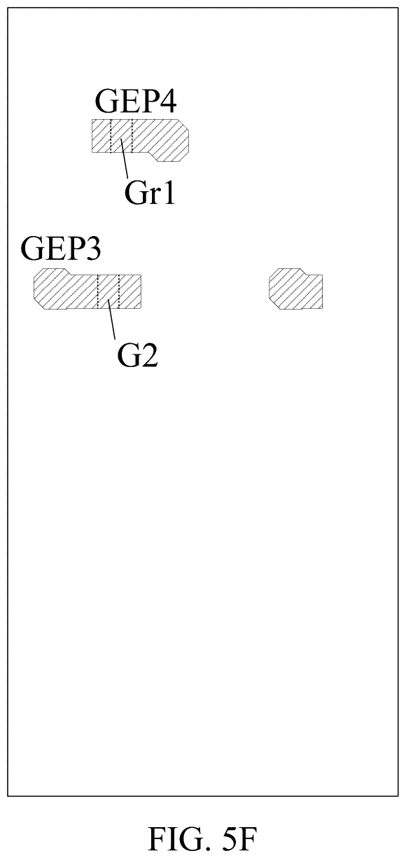

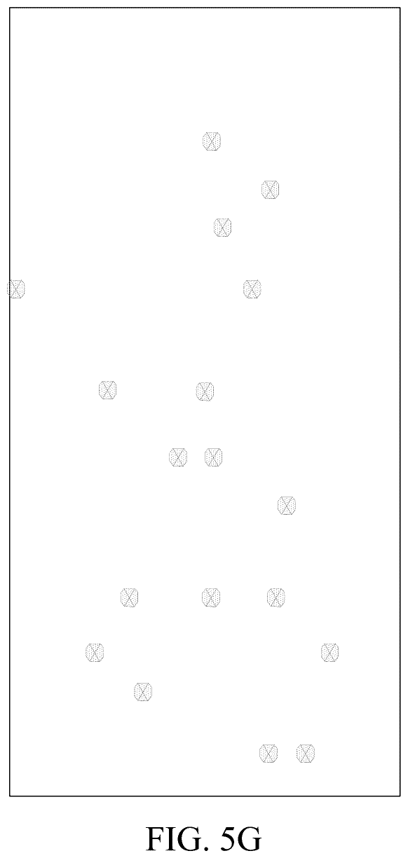

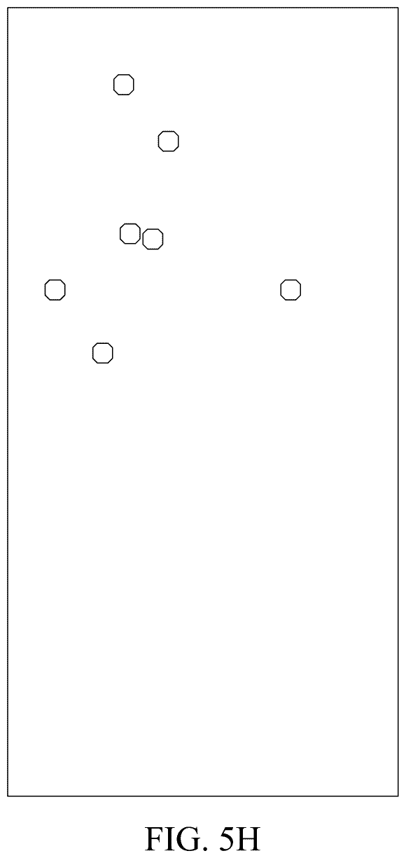

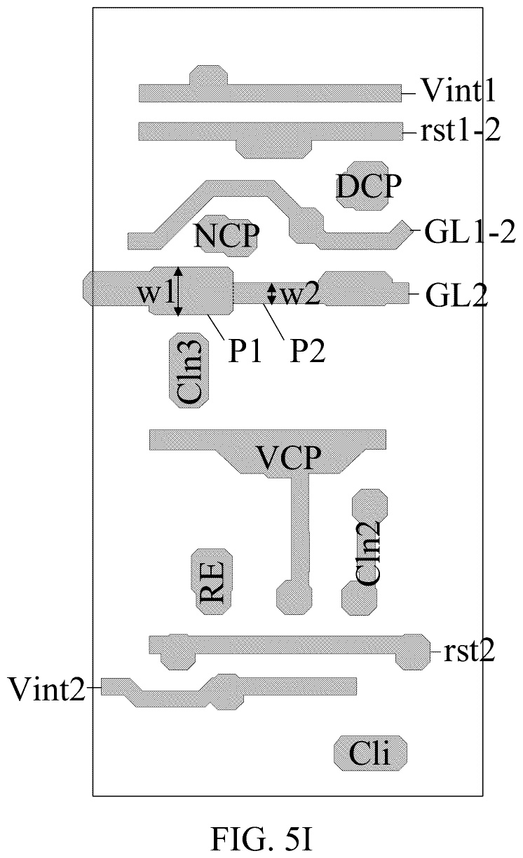

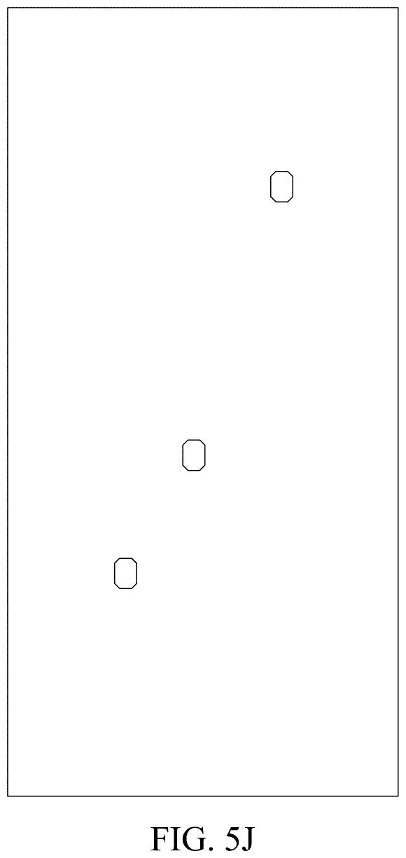

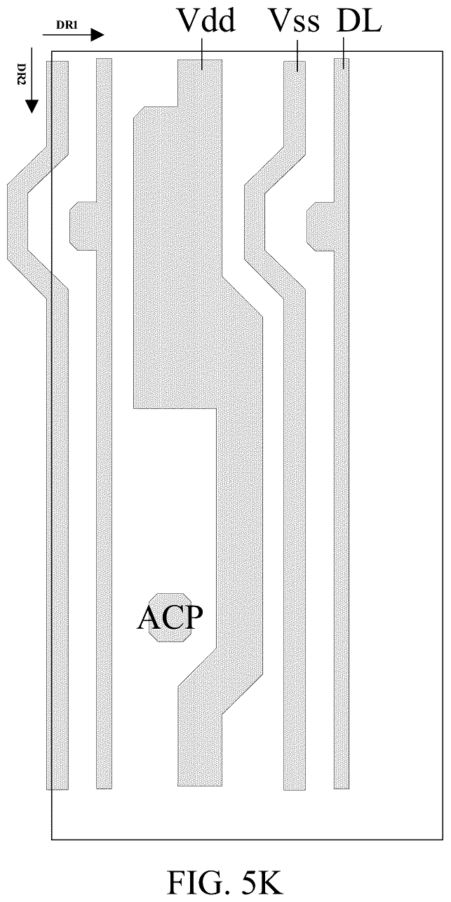

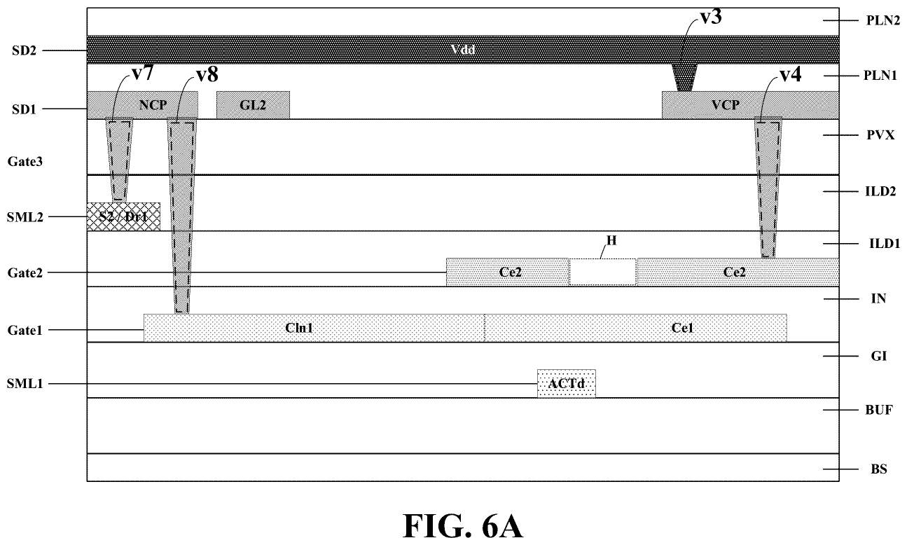

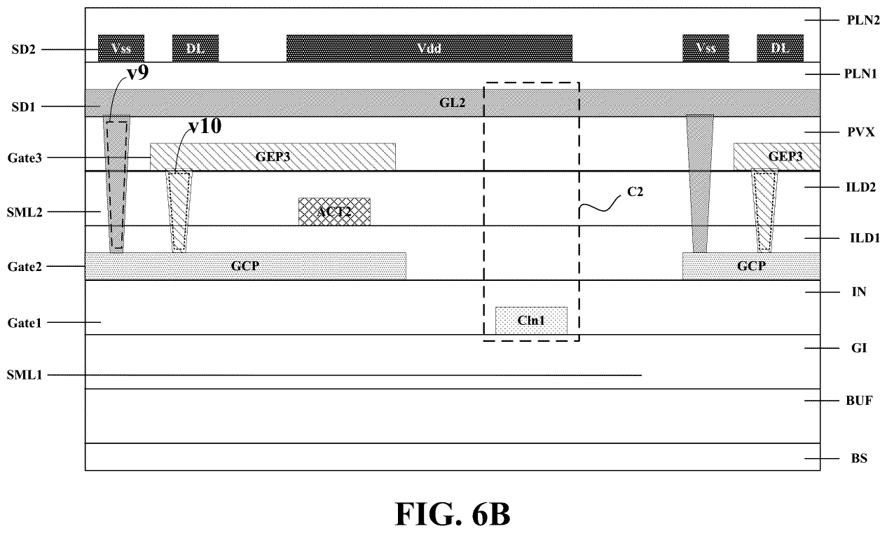

FIG. 5A is a diagram illustrating the structure of a pixel driving circuit in an array substrate in some embodiments according to the present disclosure. FIG. 5B is a diagram illustrating the structure of a first semiconductor material layer in the array substrate depicted in FIG. 5A. FIG. 5C is a diagram illustrating the structure of a first gate metal layer in the array substrate depicted in FIG. 5A. FIG. 5D is a diagram illustrating the structure of a second gate metal layer in the array substrate depicted in FIG. 5A. FIG. 5E is a diagram illustrating the structure of a second semiconductor material layer in the array substrate depicted in FIG. 5A. FIG. 5F is a diagram illustrating the structure of a third gate metal layer in the array substrate depicted in FIG. 5A. FIG. 5G is a diagram illustrating vias extending through a first inter-layer dielectric layer in the array substrate depicted in FIG. 5A. FIG. 5H is a diagram illustrating vias extending through a passivation layer in the array substrate depicted in FIG. 5A. FIG. 5I is a diagram illustrating the structure of a first signal line layer in the array substrate depicted in FIG. 5A. FIG. 5J is a diagram illustrating vias extending through a first planarization layer in the array substrate depicted in FIG. 5A. FIG. 5K is a diagram illustrating the structure of a second signal line layer in the array substrate depicted in FIG. 5A. FIG. 6A is a cross-sectional view along a C-C′ line in FIG. 5A. FIG. 6B is a cross-sectional view along a D-D′ line in FIG. 5A.

Referring to FIG. 5A to FIG. 5K, and FIG. 6A to FIG. 6B, the array substrate in some embodiments includes a base substrate BS, a buffer layer BUF on the base substrate BS, a first semiconductor material layer SML1 on a side of the buffer layer BUF away from the base substrate BS, a gate insulating layer G1 on a side of the first semiconductor material layer SML1 away from the base substrate BS, a first gate metal layer Gate1 on a side of the gate insulating layer G1 away from the first semiconductor material layer SML1, an insulating layer IN on a side of the first gate metal layer Gate1 away from the gate insulating layer G1, a second gate metal layer Gate2 on a side of the insulating layer IN away from the first gate metal layer Gate1, a first inter-layer dielectric layer ILD1 on a side of the second gate metal layer Gate2 away from the insulating layer IN, a second semiconductor material layer SML2 on a side of the first inter-layer dielectric layer ILD1 away from the second gate metal layer Gate2, a second inter-layer dielectric layer ILD2 on a side of the second semiconductor material layer SML2 away from the first inter-layer dielectric layer ILD1, a third gate metal layer Gate3 on a side of the second inter-layer dielectric layer ILD2 away from the second semiconductor material layer SML2, a passivation layer PVX on a side of the third gate metal layer Gate3 away from the second inter-layer dielectric layer ILD2, a first signal line layer SD1 on a side of the passivation layer PVX away from the third gate metal layer Gate3, a first planarization layer PLN1 on a side of the first signal line layer SD1 away from the passivation layer PVX, a second signal line layer SD2 on a side of the first planarization layer PLN1 away from the first signal line layer SD1, and a second planarization layer PLN2 on a side of the second signal line layer SD2 away from the first planarization layer PLN1.

Referring to FIG. 2A, FIG. 5A, FIG. 5B, FIG. 6A, and FIG. 6B, the first semiconductor material layer SML1 in some embodiments includes at least active layers of multiple transistors of the pixel driving circuit, including the first transistor T1, the third transistor T3, the fourth transistor T4, the second reset transistor Tr2, the third reset transistor Tr3, and the driving transistor Td. Optionally, the first semiconductor material layer SML1 further includes at least respective portions of first electrodes of multiple transistors of the pixel driving circuit, including the first transistor T1, the third transistor T3, the fourth transistor T4, the second reset transistor Tr2, the third reset transistor Tr3, and the driving transistor Td. Optionally, the first semiconductor material layer SML1 further includes at least respective portions of second electrodes of multiple transistors of the pixel driving circuit, including the first transistor T1, the third transistor T3, the fourth transistor T4, the second reset transistor Tr2, the third reset transistor Tr3, and the driving transistor Td. Optionally, the first semiconductor material layer SML1 includes active layers, first electrodes, and second electrodes of multiple transistors of the pixel driving circuit, including the first transistor T1, the third transistor T3, the fourth transistor T4, the second reset transistor Tr2, the third reset transistor Tr3, and the driving transistor Td. Various appropriate semiconductor materials may be used for making the first semiconductor material layer SML1. Examples of the semiconductor materials for making the first semiconductor material layer SML1 include silicon-based semiconductor materials such as polycrystalline silicon, single-crystal silicon, and amorphous silicon.

FIG. 5B is annotated with labels indicating components of each of multiple transistors (T1, T3, T4, Tr2, Tr3, and Td) in the pixel driving circuit. For example, the first transistor T1 includes an active layer ACT1, a first electrode S1, and a second electrode D1. The third transistor T3 includes an active layer ACT3, a first electrode S3, and a second electrode D3. The fourth transistor T4 includes an active layer ACT4, a first electrode S4, and a second electrode D4. The second reset transistor Tr2 includes an active layer ACTr2, a first electrode Sr2, and a second electrode Dr2. The third reset transistor Tr3 includes an active layer ACTr3, a first electrode Sr3, and a second electrode Dr3. The driving transistor Td includes an active layer ACTd, a first electrode Sd, and a second electrode Dd.

Optionally, the active layers (ACT1, ACT3, ACT4, ACTr2, ACTr3, and ACTd), the first electrodes (S1, S3, S4, Sr2, Sr3, and Sd), and the second electrodes (D1, D3, D4, Dr2, Dr3, and Dd) of the respective transistors (T1, T3, T4, Tr2, Tr3, and Td) are in a same layer.

In some embodiments, the active layers (ACT1, ACT3, ACT4, ACTr2, and ACTd), at least portions of the first electrodes (S1, S3, S4, Sr2, and Sd), and at least portions of the second electrodes (D1, D3, D4, Dr2, and Dd) of multiple transistors (T1, T3, T4, Tr2, and Td) in the pixel driving circuit are parts of a unitary structure. Optionally, a part of the third reset transistor Tr3 (ACTr3, Sr3, Dr3) in the first semiconductor material layer is spaced apart from the unitary structure (T1, T3, T4, Tr2, and Td) in a same pixel driving circuit.

Referring to FIG. 2A, FIG. 5A, FIG. 5C, FIG. 6A, and FIG. 6B, the first gate metal layer Gate1 in some embodiments includes at least portions of a plurality of first gate lines (e.g., a respective first gate line first branch GL1-1), a plurality of light emitting control signal lines (e.g., a respective light emitting control signal line em), a first gate electrode pad GEP1, a second gate electrode pad GEP2, and a first capacitor electrode Ce1 of the storage capacitor Cst. The array substrate depicted in FIG. 5A differs from the array substrate depicted in FIG. 3A at least in that the first gate metal layer Gate1 in the array substrate depicted in FIG. 5A further includes a first node connecting line Cln1.

In some embodiments, the first node connecting line Cln1 in the pixel driving circuit connects multiple components of the pixel driving circuit to the node N1. Referring to FIG. 6A, the first node connecting line Cln1 is connected to the first capacitor electrode Ce1, and connected to the second transistor T2 (e.g., to the first electrode S2 of the second transistor T2) through a node connecting pad NCP in the first signal line layer SD1. Optionally, the first node connecting line Cln1 corresponds to the node N1 depicted in FIG. 2A.

In some embodiments, the first node connecting line Cln1 crosses over a respective second gate line GL2 of the plurality of second gate lines. As shown in FIG. 5A, FIG. 5D, and FIG. 6A, the first node connecting line Cln1 crosses over the respective second gate line in the second gate metal layer Gate2. An orthographic projection of the first node connecting line Cln1 on a base substrate at least partially overlaps with an orthographic projection of the respective second gate line on the base substrate.

In some embodiments, the first node connecting line Cln1 and the first capacitor electrode Ce1 of the storage capacitor Cst are parts of a unitary structure. The first node connecting line Cln1 extends away from the first capacitor electrode Ce1 of the storage capacitor Cst.

In some embodiments, a respective first gate line includes multiple branches respectively in multiple layers. In one example, the respective first gate line includes a respective first gate line first branch GL1-1 in the first gate metal layer Gate1 (as shown in FIG. 5C) and a respective first gate line second branch GL1-2 in the first signal line layer SD1 (as shown in FIG. 5I). Optionally, an orthographic projection of the respective first gate line first branch GL1-1 on a base substrate BS at least partially (e.g., at least 80%, at least 85%, at least 90%, at least 95%, at least 98%, or at least 99%) overlaps with an orthographic projection of the respective first gate line second branch GL1-2 on the base substrate BS.

Various appropriate electrode materials and various appropriate fabricating methods may be used to make the first gate metal layer Gate1. For example, a conductive material may be deposited on the substrate by a plasma-enhanced chemical vapor deposition (PECVD) process and patterned. Examples of appropriate conductive materials for making the first gate metal layer Gate1 include, but are not limited to, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. Optionally, the at least portions of the plurality of first gate lines (e.g., the respective first gate line first branch GL1-1), the plurality of light emitting control signal lines (e.g., the respective light emitting control signal line em), the first gate electrode pad GEP1, the second gate electrode pad GEP2, the first capacitor electrode Ce1 of the storage capacitor Cst, and first node connecting line Cln1 are in a same layer.

In some embodiments, the first gate electrode pad GEP1 includes the gate electrode Gr2 of the second reset transistor Tr2 in the pixel driving circuit. In some embodiments, the second gate electrode pad GEP2 includes the gate electrode Gr3 of the third reset transistor Tr3 in the pixel driving circuit. The first gate electrode pad GEP1 and the second gate electrode pad GEP2 are connected to a respective second reset control signal line rst2 of a plurality of second reset control signal lines, respectively.

Referring to FIG. 2A, FIG. 5A, FIG. 5D, FIG. 6A, and FIG. 6B, the second gate metal layer Gate2 in some embodiments includes at least portions of a plurality of first reset control signal lines (e.g., a respective first reset control signal line first branch rst1-1), a plurality of third reset signal lines (e.g., a respective third reset signal line Vint3), a gate connecting pad GCP and a second capacitor electrode Ce2 of the storage capacitor Cst. Various appropriate electrode materials and various appropriate fabricating methods may be used to make the second gate metal layer Gate2. For example, a conductive material may be deposited on the substrate by a plasma-enhanced chemical vapor deposition (PECVD) process and patterned. Examples of appropriate conductive materials for making the second gate metal layer Gate2 include, but are not limited to, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. Optionally, the at least portions of the plurality of first reset control signal lines (e.g., the respective first reset control signal line first branch rst1-1), the plurality of third reset signal lines (e.g., the respective third reset signal line Vint3), the gate connecting pad GCP, and the second capacitor electrode Ce2 of the storage capacitor Cst are in a same layer.

The array substrate depicted in FIG. 5A differs from the array substrate depicted in FIG. 3A at least in that the second gate metal layer Gate2 in the array substrate depicted in FIG. 5A does not include the plurality of second gate lines (e.g., the respective second gate line GL2). The second gate metal layer Gate2 in the array substrate depicted in FIG. 5A, however, includes a gate connecting pad GCP. Referring to FIG. 6B, the gate connecting pad GCP connects the third gate electrode pad GEP3 in the third gate metal layer Gate3 to a respective second gate line GL2 of a plurality of second gate lines in the first signal line layer SD1. Gate scanning signals provided by the respective second gate line GL2 is transmitted to the gate electrode G2 of the second transistor T2 through the gate connecting pad GCP.

Referring to FIG. 6B, in some embodiments, the respective second gate line GL2 is connected to the gate connecting pad GCP through a ninth via v9. The third gate electrode pad GEP3 is connected to the gate connecting pad GCP through a tenth via v10. In one example, the ninth via v9 extends through the passivation layer PVX, the second inter-layer dielectric layer ILD2, and the first inter-layer dielectric layer ILD1. In another example, the tenth via v10 extends through the second inter-layer dielectric layer ILD2 and the first inter-layer dielectric layer ILD1.

In some embodiments, a respective first reset control signal line includes multiple branches respectively in multiple layers. In one example, the respective first reset control signal line includes a respective first reset control signal line first branch rst1-1 in the second gate metal layer Gate2 (as shown in FIG. 5D) and a respective first reset control signal line second branch rst1-2 in the first signal line layer SD1 (as shown in FIG. 5I). Optionally, an orthographic projection of the respective first reset control signal line first branch rst1-1 on a base substrate BS at least partially (e.g., at least 80%, at least 85%, at least 90%, at least 95%, at least 98%, or at least 99%) overlaps with an orthographic projection of the respective first reset control signal line second branch rst1-2 on the base substrate BS.

Referring to FIG. 2A, FIG. 5A, FIG. 5E, FIG. 6A, and FIG. 6B, the second semiconductor material layer SML2 in some embodiments includes at least an active layer ACT2 of the second transistor T2 and an active layer ACTr1 of the first reset transistor Tr1. Optionally, the second semiconductor material layer SML2 further includes at least a portion of a first electrode S2 of the second transistor T2 and at least a portion of a first electrode Sr1 of the first reset transistor Tr1. Optionally, the second semiconductor material layer SML2 further includes at least a portion of a second electrode D2 of the second transistor T2 and at least a portion of a second electrode Dr1 of the first reset transistor Tr1. Optionally, the second semiconductor material layer SML2 includes the active layer ACT2, the first electrode S2, and the second electrode D2 of the second transistor T2; and the active layer ACTr1, the first electrode Sr1, and the second electrode Dr1 of the first reset transistor Tr1. In the present array substrate, at least the active layer ACT2 of the second transistor T2 and the active layer ACTr1 of the first reset transistor Tr1 are in a layer different from at least the active layers of other transistors. Various appropriate semiconductor materials may be used for making the second semiconductor material layer SML2. Examples of the semiconductor materials for making the second semiconductor material layer SML2 include metal oxide-based semiconductor material such as indium gallium zinc oxide and metal oxynitride-based semiconductor materials such as zinc oxynitride.

FIG. 5E is annotated with labels indicating components of the second transistor T2 and the first reset transistor Tr1. For example, the second transistor T2 includes an active layer ACT2, a first electrode S2, and a second electrode D2; and the first reset transistor Tr1 includes an active layer ACTr1, a first electrode Sr1, and a second electrode Dr1. Optionally, the active layer ACT2, the first electrode S2, the second electrode D2 of the second transistor T2; and the active layer ACTr1, the first electrode Sr1, and the second electrode Dr1 of the first reset transistor Tr1 are in a same layer. Optionally, the active layer ACT2 of the second transistor T2 and the active layer ACTr1 of the first reset transistor Tr1 are parts of a unitary structure. Optionally, the active layer ACT2, the first electrode S2, the second electrode D2 of the second transistor T2; and the active layer ACTr1, the first electrode Sr1, and the second electrode Dr1 of the first reset transistor Tr1 are parts of a unitary structure.

Referring to FIG. 2A, FIG. 5A, FIG. 5F, FIG. 6A, and FIG. 6B, the third gate metal layer Gate3 in some embodiments includes a third gate electrode pad GEP3 and a fourth gate electrode pad GEP4. Various appropriate electrode materials and various appropriate fabricating methods may be used to make the third gate metal layer Gate3. For example, a conductive material may be deposited on the substrate by a plasma-enhanced chemical vapor deposition (PECVD) process and patterned. Examples of appropriate conductive materials for making the third gate metal layer Gate3 include, but are not limited to, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. Optionally, the third gate electrode pad GEP3 and the fourth gate electrode pad GEP4 are in a same layer.

In some embodiments, the third gate electrode pad GEP3 includes the gate electrode G2 of the second transistor T2 in the pixel driving circuit. In some embodiments, the fourth gate electrode pad GEP4 includes the gate electrode Gr1 of the first reset transistor Tr1 in the pixel driving circuit. The third gate electrode pad GEP3 is connected to a respective second gate line GL2 of a plurality of second gate lines through a gate connecting pad (“GCP” in FIG. 5D). The fourth gate electrode pad GEP4 is connected to a respective first reset control signal line rst1 of a plurality of first reset control signal lines. In one example, the fourth gate electrode pad GEP4 is connected to a respective first reset control signal line second branch (“rst1-2” in FIG. 5I).

Vias extending through the first inter-layer dielectric layer ILD1 are depicted in FIG. 5G.

Vias extending through the passivation layer PVX are depicted in FIG. 5H.

Referring to FIG. 2A, FIG. 5A, FIG. 5I, FIG. 6A, and FIG. 6B, the first signal line layer SD1 in some embodiments includes a plurality of second gate lines (e.g., a respective second gate line GL2), a plurality of first reset signal lines (e.g., a respective first reset signal line Vint1); a plurality of second reset signal lines (e.g., a respective second reset signal line Vint2); at least portions of a plurality of first reset control signal lines (e.g., a respective first reset control signal line second branch rst1-2), at least portions of a plurality of first gate lines (e.g., a respective first gate line second branch GL1-2), a plurality of second reset control signal lines (e.g., a respective second reset control signal line rst2); a node connecting pad NCP; a relay electrode RE; a second node connecting line Cln2; a third node connecting line Cln3; a voltage connecting pad VCP; a data signal connecting pad DCP; and a reset signal connecting pad Cli.

Various appropriate conductive materials and various appropriate fabricating methods may be used to make the first signal line layer SD1. For example, a conductive material may be deposited on the substrate by a plasma-enhanced chemical vapor deposition (PECVD) process and patterned. Examples of appropriate conductive materials for making the first signal line layer include, but are not limited to, titanium, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. In some embodiments, the first signal line layer includes a plurality of sub-layers stacked together. In one example, the first signal line layer includes a stacked titanium/aluminum/titanium multi-layer structure. In another example, the first signal line layer includes a stacked molybdenum/aluminum/molybdenum multi-layer structure.

Optionally, the plurality of second gate lines (e.g., the respective second gate line GL2), the plurality of first reset signal lines (e.g., the respective first reset signal line Vint1); the plurality of second reset signal lines (e.g., the respective second reset signal line Vint2); at least portions of the plurality of first reset control signal lines (e.g., the respective first reset control signal line second branch rst1-2), at least portions of the plurality of first gate lines (e.g., the respective first gate line second branch GL1-2), the plurality of second reset control signal lines (e.g., the respective second reset control signal line rst2); the node connecting pad NCP; the relay electrode RE; the second node connecting line Cln2; the third node connecting line Cln3; the voltage connecting pad VCP; the data signal connecting pad DCP; and the reset signal connecting pad Cli are in a same layer.

In some embodiments, the node connecting pad NCP in the pixel driving circuit connects multiple components of the pixel driving circuit to the node N1. Referring to FIG. 6A, the node connecting pad NCP is connected to the first node connecting line Cln1 through an eighth via v8, and connected to the second transistor T2 (e.g., to the first electrode S2 of the second transistor T2) through a seventh via v7. The first node connecting line Cln1 is connected to the first capacitor electrode Ce1. Optionally, the first node connecting line Cln1 corresponds to the node N1 depicted in FIG. 2A. In one example, the seventh via v7 extends through the passivation layer PVX and the second inter-layer dielectric layer ILD2. In another example, the eighth via v8 extends through the passivation layer PVX, the second inter-layer dielectric layer ILD2, the first inter-layer dielectric layer ILD1, and the insulating layer IN. In another example, the node connecting pad NCP is in the first signal line layer SD1, the first node connecting line Cln1 and the first capacitor electrode Ce1 are in the first gate metal layer Gate1, and the first electrode S2 of the second transistor T2 is in the second semiconductor material layer SML2.

Referring to FIG. 2A, FIG. 5A, FIG. 5C, FIG. 5D, and FIG. 6A, in some embodiments, in a hole region H, a portion of the second capacitor electrode Ce2 is absent. Optionally, an orthographic projection of the second capacitor electrode Ce2 on a base substrate BS substantially (e.g., at least 80%, at least 85%, at least 90%, at least 95%, at least 98%, at least 99%, or 100%) covers, with a margin, an orthographic projection of the first capacitor electrode Ce1 on the base substrate BS except for the hole region H in which a portion of the second capacitor electrode Ce2 is absent. In alternative embodiments, the array substrate does not have a hole region H, and the orthographic projection of the second capacitor electrode Ce2 on the base substrate BS completely covers, with a margin, the orthographic projection of the first capacitor electrode Ce1 on the base substrate BS.

Referring to FIG. 5A, FIG. 5I, FIG. 5K, and FIG. 6A, the data signal connecting pad DCP in the pixel driving circuit connects the respective data line DL to the first electrode S1 of the first transistor T1, data signals provided by the respective data line DL is transmitted to the first electrode S1 of the first transistor T1 through the signal connecting pad DCP.

In some embodiments, a respective first gate line includes multiple branches respectively in multiple layers. In one example, the respective first gate line includes a respective first gate line first branch GL1-1 in the first gate metal layer Gate1 (as shown in FIG. 5C) and a respective first gate line second branch GL1-2 in the first signal line layer SD1 (as shown in FIG. 5I). Optionally, an orthographic projection of the respective first gate line first branch GL1-1 on a base substrate BS at least partially (e.g., at least 80%, at least 85%, at least 90%, at least 95%, at least 98%, or at least 99%) overlaps with an orthographic projection of the respective first gate line second branch GL1-2 on the base substrate BS.

In some embodiments, a respective first reset control signal line includes multiple branches respectively in multiple layers. In one example, the respective first reset control signal line includes a respective first reset control signal line first branch rst1-1 in the second gate metal layer Gate2 (as shown in FIG. 5D) and a respective first reset control signal line second branch rst1-2 in the first signal line layer SD1 (as shown in FIG. 5I). Optionally, an orthographic projection of the respective first reset control signal line first branch rst1-1 on a base substrate BS at least partially (e.g., at least 80%, at least 85%, at least 90%, at least 95%, at least 98%, or at least 99%) overlaps with an orthographic projection of the respective first reset control signal line second branch rst1-2 on the base substrate BS.

Referring to FIG. 5A, FIG. 5D, FIG. 5F, FIG. 5I, FIG. 6A, and FIG. 6B, the gate connecting pad GCP in the second gate metal layer Gate2 connects the third gate electrode pad GEP3 in the third gate metal layer Gate3 to a respective second gate line GL2 of a plurality of second gate lines in the first signal line layer SD1. Gate scanning signals provided by the respective second gate line GL2 is transmitted to the gate electrode G2 of the second transistor T2 through the gate connecting pad GCP. Referring to FIG. 6B, the respective second gate line GL2 is connected to the gate connecting pad GCP through a ninth via v9. The third gate electrode pad GEP3 is connected to the gate connecting pad GCP through a tenth via v10. In one example, the ninth via v9 extends through the passivation layer PVX, the second inter-layer dielectric layer ILD2, and the first inter-layer dielectric layer ILD1. In another example, the tenth via v10 extends through the second inter-layer dielectric layer ILD2 and the first inter-layer dielectric layer ILD1.

Referring to FIG. 5A, FIG. 5D, FIG. 5I, FIG. 5K, FIG. 6A, and FIG. 6B, the voltage connecting pad VCP connects a respective first voltage supply line Vdd with the second capacitor electrode Ce2 of the storage capacitor. Referring to FIG. 6A, the respective first voltage supply line Vdd is connected to the voltage connecting pad VCP through a third via v3. The voltage connecting pad VCP is connected to the second capacitor electrode Ce2 of the storage capacitor through a fourth via v4. In one example, the third via v3 extends through the first planarization layer PLN1. In another example, the fourth via v4 extends through the passivation layer PVX, the second inter-layer dielectric layer ILD2, and the first inter-layer dielectric layer ILD1.

Referring to FIG. 5A, FIG. 5B, FIG. 5I, FIG. 5K, FIG. 6A, and FIG. 6B, the relay electrode RE connects an anode connecting pad ACP with a first electrode S4 of the fourth transistor T4 in the pixel driving circuit. The anode connecting pad ACP is further connected to an anode of a light emitting element.

Referring to FIG. 5A, FIG. 5B, FIG. 5D, FIG. 5I, FIG. 6A, and FIG. 6B, the reset signal connecting line Cli connects the respective third reset signal line Vint3 with the first electrode Sr3 of the third reset transistor Tr3 in the pixel driving circuit, thereby providing a reset signal to the first electrode Sr3 of the third reset transistor Tr3 in the pixel driving circuit.

Referring to FIG. 5A, FIG. 5B, FIG. 5I, FIG. 6A, and FIG. 6B, the second node connecting line Cln2 in the pixel driving circuit is connected to a second electrode D3 of the third transistor T3 in the pixel driving circuit, and connected to a second electrode Dr3 of the third reset transistor Tr3 in the pixel driving circuit.

Referring to FIG. 5A, FIG. 5B, FIG. 5I, FIG. 6A, and FIG. 6B, the third node connecting line Cln3 in the pixel driving circuit is connected to a second electrode D2 of the second transistor T2 in the pixel driving circuit, and connected to a second electrode Dd of the driving transistor Td and a first electrode S4 of the fourth transistor T4 in the pixel driving circuit.

Vias extending through the first planarization layer PLN1 are depicted in FIG. 5J.

Referring to FIG. 2A, FIG. 5A, FIG. 5K, FIG. 6A, and FIG. 6B, the second signal line layer SD2 in some embodiments includes a plurality of first voltage supply lines (e.g., a respective first voltage supply line Vdd), a plurality of second voltage supply lines (e.g., a respective second voltage supply line Vss), a plurality of data lines (e.g., a respective data line DL), and an anode contact pad ACP. Various appropriate conductive materials and various appropriate fabricating methods may be used to make the second signal line layer SD2. For example, a conductive material may be deposited on the substrate by a plasma-enhanced chemical vapor deposition (PECVD) process and patterned. Examples of appropriate conductive materials for making the second signal line layer SD2 include, but are not limited to, titanium, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like. In some embodiments, the second signal line layer includes a plurality of sub-layers stacked together. In one example, the second signal line layer includes a stacked titanium/aluminum/titanium multi-layer structure. In another example, the second signal line layer includes a stacked molybdenum/aluminum/molybdenum multi-layer structure. Optionally, the plurality of first voltage supply lines (e.g., the respective first voltage supply line Vdd), the plurality of second voltage supply lines (e.g., the respective second voltage supply line Vss), the plurality of data lines (e.g., the respective data line DL), and the anode contact pad ACP are in a same layer.

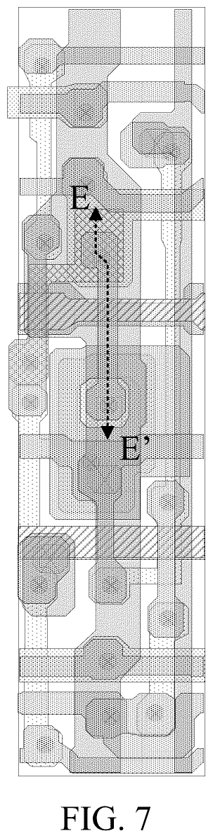

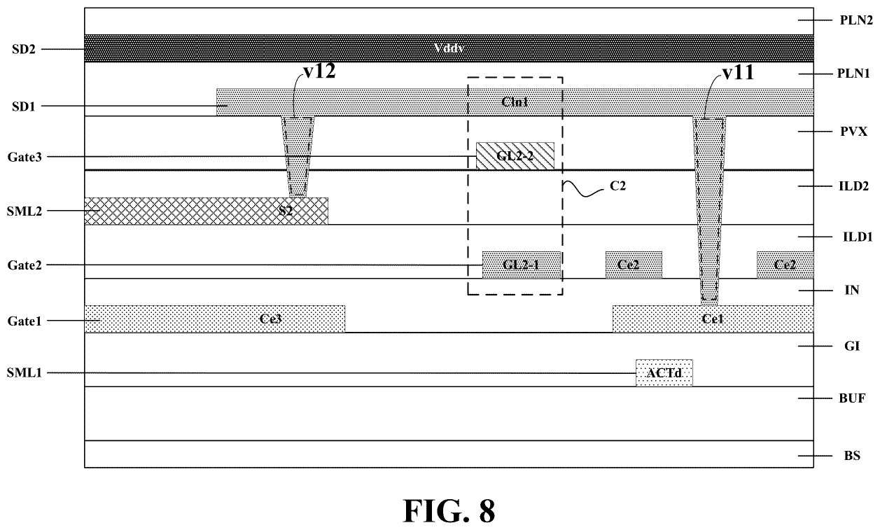

FIG. 7 is a diagram illustrating the structure of a pixel driving circuit in an array substrate in some embodiments according to the present disclosure. FIG. 8 is a cross-sectional view along a E-E′ line in FIG. 7. FIG. 7 and FIG. 8 depict an array substrate in an alternative embodiment. Referring to FIG. 7, the array substrate in the alternative embodiment includes a first node connecting line Cln1 in the first signal line layer SD1. The first node connecting line Cln1 connects multiple components of the pixel driving circuit to the node N1. Referring to FIG. 8, the first node connecting line Cln1 is connected to the first capacitor electrode Ce1 through an eleventh via v11, and connected to the second transistor T2 (e.g., to the first electrode S2 of the second transistor T2) through a twelfth via v12.

In the alternative embodiment depicted in FIG. 7 and FIG. 8, a respective second gate line of a plurality of second gate lines includes multiple branches respectively in multiple layers. In one example, the respective second gate line includes a respective second gate line first branch GL2-1 in the second gate metal layer Gate2 and a respective second gate line second branch GL2-2 in the third gate metal layer Gate3. Optionally, an orthographic projection of the respective second gate line first branch GL2-1 on a base substrate BS at least partially (e.g., at least 80%, at least 85%, at least 90%, at least 95%, at least 98%, or at least 99%) overlaps with an orthographic projection of the respective second gate line second branch GL2-2 on the base substrate BS.

In the alternative embodiment depicted in FIG. 7 and FIG. 8, the first node connecting line Cln1 crosses over the respective second gate line first branch GL2-1 in the second gate metal layer Gate2 and the respective second gate line second branch GL2-2 in the third gate metal layer Gate3. The inventors of the present disclosure discover that, by having the first node connecting line Cln1 crossing over two layers of second gate line branches, the presence of the two layers of second gate line branches underneath the first node connecting line Cln1 renders a surface of the passivation layer PVX uneven where the first node connecting line Cln1 crosses over the respective second gate line first branch GL2-1 in the second gate metal layer Gate2 and the respective second gate line second branch GL2-2 in the third gate metal layer Gate3.

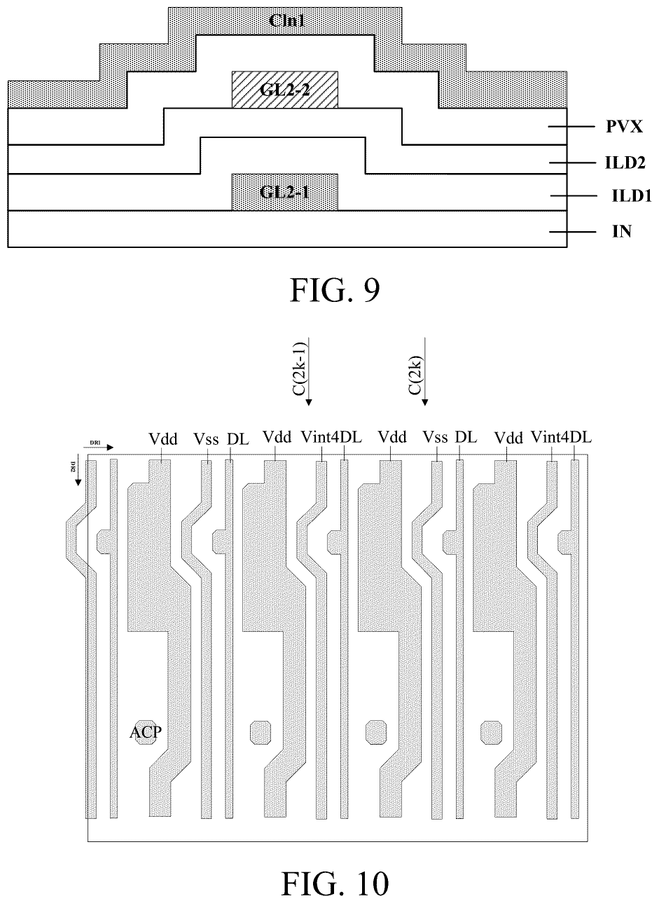

FIG. 9 is a cross-sectional view of a region where a first node connecting line crosses over a respective second gate line first branch and a respective second gate line second branch. As shown in FIG. 9, the presence of the respective second gate line first branch GL2-1 in the second gate metal layer Gate2 and the respective second gate line second branch GL2-2 in the third gate metal layer Gate3 form a relatively steep slope over which the first node connecting line Cln1 climbs. The inventors of the present disclosure discover that the relatively steep slope results in an increased loading in the first node connecting line Cln1, and an overall increased loading in the pixel driving circuit having the first node connecting line Cln1. Compared to FIG. 9, the array substrate depicted in FIG. 4A and FIG. 6A does not have a slope where the first node connecting line Cln1 crosses over the respective second gate line GL2.

In the array substrate, there are two parasitic capacitors, C1 and C2. The first capacitor C1 is formed between the second semiconductor material layer (e.g., a unitary structure comprising the active layer ACT2 of the second transistor and the active layer ACTr1 of the first reset transistor depicted in FIG. 3E or FIG. 5E) and the respective first gate line (e.g., including the respective first gate line first branch GL1-1 in the first gate metal layer and the respective first gate line second branch GL1-2 in the first signal line layer). The second capacitor C2 is formed between the first node connecting line Cln1 and the respective second gate line. The inventors of the present disclosure discover that a higher ratio of C1 to C2 is conducive to achieving an increased dark state margin. The dark state margin refers to the difference in voltage between the voltage required to turn off a subpixel completely and the voltage required to produce a small amount of light emission in the subpixel. When the dark state margin is too small, it can result in “false contouring” or “image retention”. An increased dark state margin avoids the “false contouring” or “image retention”.

Referring to FIG. 8 and FIG. 9, when the first node connecting line Cln1 crosses over two of second gate line branches (including the respective second gate line first branch GL2-1 in the second gate metal layer Gate2 and the respective second gate line second branch GL2-2 in the third gate metal layer Gate3), a capacitance of the second capacitor C2 increases, leading to a decreased dark state margin.

The inventors of the present disclosure discover that, by having the first node connecting line Cln1 crossing over only one layer of second gate line (see, e.g., FIG. 4A or FIG. 6A), the capacitance of the second capacitor C2 can be decreased, leading to an increased dark state margin.

Referring to FIG. 3D or FIG. 5I, the respective second gate line GL2 in some embodiments includes a first portion P1 and a second portion P2. Referring to FIG. 3A to FIG. 3K, and FIG. 5A to FIG. 5K, in some embodiments, an orthographic projection of the first portion P1 on a base substrate at least partially overlaps with an orthographic projection of the active layer ACT2 of the second transistor T2 on the base substrate, and is non-overlapping with an orthographic projection of the first node connecting line Cln1 on the base substrate. In some embodiments, an orthographic projection of the second portion P2 on a base substrate at least partially overlaps with an orthographic projection of the first node connecting line Cln1 on the base substrate, and is non-overlapping with an orthographic projection of the active layer ACT2 of the second transistor T2 on the base substrate.

In some embodiments, the first portion P1 has a first average line width w1 where the first portion P1 crosses over the active layer ACT2 of the second transistor T2, and the second portion P2 has a second average line width w2 where the second portion P2 crosses over the first connecting line Cln1. In some embodiments, the respective second gate line GL2 extends along a first direction. The first average line width w1 and the second average line width w2 are line widths along a second direction perpendicular to the first direction.

In some embodiments, the first average line width w1 is greater than the second average line width w2. The inventors of the present disclosure discover that, by having a relatively smaller second average line width, an overlapping area between the respective second gate line GL2 and the first connecting line Cln1 can be further decreased, and the capacitance of the second capacitor C2 can be further decreased, leading to an increased dark state margin.

Referring to FIG. 3A, FIG. 3K, FIG. 5A, and FIG. 5K, the array substrate in some embodiments includes a plurality of first voltage supply lines, a plurality of second voltage supply lines, and a plurality of data lines alternately arranged. Each of the plurality of first voltage supply lines, the plurality of second voltage supply lines, and the plurality of data lines extends along a direction substantially parallel to a second direction DR2. As used herein, the term “substantially parallel” means that an angle is in the range of 0 degree to approximately 45 degrees, e.g., 0 degree to approximately 5 degrees, 0 degree to approximately 10 degrees, 0 degree to approximately 15 degrees, 0 degree to approximately 20 degrees, 0 degree to approximately 25 degrees, 0 degree to approximately 30 degrees.

In some embodiments, the second signal line layer further includes a plurality of fourth reset signal lines extending along a direction substantially parallel to a second direction DR2. FIG. 10 is a diagram illustrating the structure of a second signal line layer in an array substrate in some embodiments according to the present disclosure. Referring to FIG. 10, the array substrate in some embodiments includes a plurality of first voltage supply lines, a plurality of second voltage supply lines, a plurality of fourth reset signal lines (e.g., a respective fourth reset signal line Vint4), and a plurality of data lines. In some embodiments, the plurality of pixel driving circuits are arranged in columns, including (2k-1)-th column C(2k-1), and (2k)-th column C(2k) of K columns, K and k being positive integers, 1≤k≤(K/2). Referring to FIG. 10, in some embodiments, the plurality of fourth reset signal lines are present in the (2k-1)-th column C(2k-1), and are absent in the (2k)-th column C(2k). The plurality of second voltage supply lines are present in the (2k)-th column C(2k), and are absent in the (2k-1)-th column C(2k-1).

As used herein, the terms “(2k-1)-th column” and “(2k)-th column” are used in the context of the K columns. The array substrate may or may not include additional column(s) before the first column of the K columns and/or additional columns after the last column of the K columns. In the context of the array substrate, the term “(2k-1)-th column” does not necessarily denote an odd-numbered column, and the term “(2k)-th column” does not necessarily denote an even-numbered column. In one example, the (2k-1)-th column is an odd-numbered column in the context of the K columns, but may be an even-numbered column in the context of the array substrate. In another example, the (2k-1)-th column is an odd-numbered column in the context of the K columns, and also an odd-numbered column in the context of the array substrate. In one example, the (2k)-th column is an even-numbered column in the context of the K columns, but may be an odd-numbered column in the context of the array substrate. In another example, the (2k)-th column is an even-numbered column in the context of the K columns, and also an even-numbered column in the context of the array substrate.

The plurality of fourth reset signal lines may form an interconnected reset signal network. In one example, the plurality of fourth reset signal lines and the plurality of first reset signal lines form an interconnected reset signal network. In another example, the plurality of fourth reset signal lines and the plurality of second reset signal lines form an interconnected reset signal network. In another example, the plurality of fourth reset signal lines and the plurality of third reset signal lines form an interconnected reset signal network.

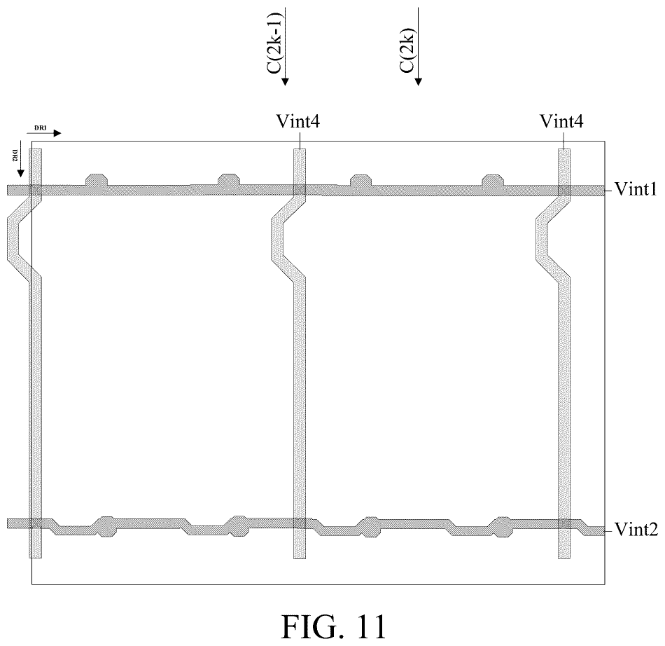

FIG. 11 illustrates an interconnected reset signal network in some embodiments according to the present disclosure. Referring to FIG. 11, the interconnected reset signal network in some embodiments includes a plurality of first reset signal lines, a plurality of second reset signal lines, and a plurality of fourth reset signal lines interconnected together. The plurality of first reset signal lines extend along a direction substantially parallel to a first direction DR1; the plurality of second reset signal lines extend along a direction substantially parallel to the first direction DR1; and the plurality of fourth reset signal lines extend along a direction substantially parallel to a second direction DR2. In one example, the plurality of first reset signal lines and the plurality of second reset signal lines are in the first signal line layer. In another example, the plurality of fourth reset signal lines are in the second signal line layer. Optionally, a respective first reset signal line Vint1 is connected to one or more fourth reset signal line of the plurality of fourth reset signal line. Optionally, a respective second reset signal line Vint2 is connected to one or more fourth reset signal line of the plurality of fourth reset signal line. Optionally, a respective fourth reset signal line Vint4 is connected to one or more first reset signal line of the plurality of first reset signal lines and connected to one or more second reset signal line of the plurality of second reset signal lines.

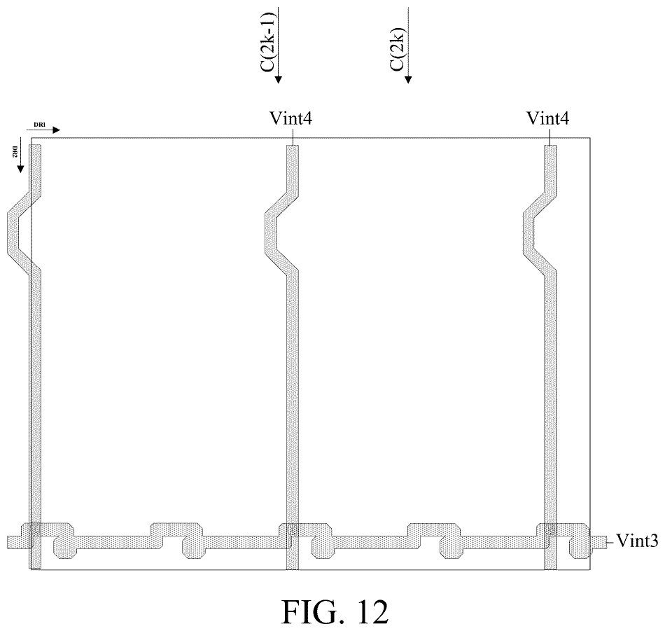

FIG. 12 illustrates an interconnected reset signal network in some embodiments according to the present disclosure. Referring to FIG. 12, the interconnected reset signal network in some embodiments includes a plurality of third reset signal lines and a plurality of fourth reset signal lines interconnected together. The plurality of third reset signal lines extend along a direction substantially parallel to a first direction DR1; and the plurality of fourth reset signal lines extend along a direction substantially parallel to a second direction DR2. In one example, the plurality of third reset signal lines are in the second gate metal layer. In another example, the plurality of fourth reset signal lines are in the second signal line layer. Optionally, a respective third reset signal line Vint3 is connected to one or more fourth reset signal line of the plurality of fourth reset signal line. Optionally, a respective fourth reset signal line Vint4 is connected to one or more third reset signal line of the plurality of third reset signal lines.

Referring to FIG. 3A, FIG. 3D, FIG. 3I, FIG. 5A, FIG. 5D, and FIG. 5I, the plurality of first reset signal lines and the plurality of second reset signal lines are in the first signal line layer; and the plurality of third reset signal lines are in the second gate metal layer.

In alternative embodiments, the plurality of first reset signal lines are in the first signal line layer; the plurality of second reset signal lines are in the second gate metal layer; and the plurality of third reset signal lines are in the third gate metal layer.

In alternative embodiments, the plurality of first reset signal lines are in the first signal line layer; the plurality of second reset signal lines are in the second gate metal layer; and the plurality of third reset signal lines are in the first signal line layer.

In alternative embodiments, the plurality of first reset signal lines are in the second gate metal layer; and the plurality of second reset signal lines are in the first signal line layer; and the plurality of third reset signal lines are in the second gate metal layer.

In alternative embodiments, the plurality of first reset signal lines are in the third gate metal layer; and the plurality of second reset signal lines are in the first signal line layer; and the plurality of third reset signal lines are in the second gate metal layer.

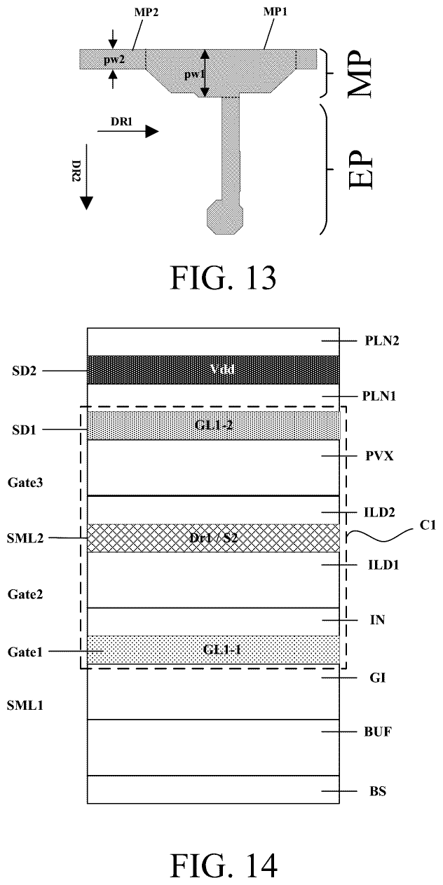

FIG. 13 is a diagram illustrating the structure of a voltage connecting pad in an array substrate in some embodiments according to the present disclosure. Referring to FIG. 13, the voltage connecting pad in some embodiments includes a main portion MP and an extension portion EP extending away from the main portion MP. In some embodiments, the main portion MP extends along a direction substantially parallel to a first direction DR1, the extension portion EP extends away from the main portion MP along a direction substantially parallel to a second direction DR2. The second direction DR2 is different from the first direction DR1. Optionally, the main portion MP and the extension portion EP are parts of a unitary structure.

Referring to FIG. 13, FIG. 3A to FIG. 3K, FIG. 4A to FIG. 4B, FIG. 5A to FIG. 5K, and FIG. 6A to FIG. 6B, in some embodiments, the array substrate in some embodiments includes a respective first voltage supply line Vdd extending along a direction substantially parallel to a second direction DR2. The main portion MP connects the respective first voltage supply line Vdd with the second capacitor electrode Ce2 of the storage capacitor. The extension portion EP connects the main portion MP with a first electrode S3 of the third transistor T3. The extension portion EP crosses over a respective light emitting control signal line em of a plurality of light emitting control signal lines. An orthographic projection of the extension portion EP on a base substrate BS partially overlaps with an orthographic projection of the respective light emitting control signal line em on the base substrate BS.

In some embodiments, the respective first voltage supply line Vdd is connected to the main portion MP through a third via v3. The main portion MP is connected to the second capacitor electrode Ce2 of the storage capacitor through a fourth via v4. In one example, the third via v3 extends through the first planarization layer PLN1. In another example, the fourth via v4 extends through the passivation layer PVX, the second inter-layer dielectric layer ILD2, and the first inter-layer dielectric layer ILD1.

In some embodiments, the main portion MP and the extension portion EP are in the first signal line layer SD1, the respective light emitting control signal line em is in the first gate metal layer Gate1, and the respective first voltage supply line Vdd is in a second signal line layer SD2.

In some embodiments, the main portion MP includes a first main part MP1 and a second main part MP2. The first main part MP1 connects the respective first voltage supply line Vdd with the second capacitor electrode Ce2 of the storage capacitor. An orthographic projection of the first main part MP1 on a base substrate BS at least partially overlaps with an orthographic projection of the second capacitor electrode Ce2 of the storage capacitor on the base substrate BS, and at least partially overlaps with an orthographic projection of the respective first voltage supply line Vdd on the base substrate BS. An orthographic projection of the second main part MP2 on a base substrate BS is non-overlapping with an orthographic projection of the second capacitor electrode Ce2 of the storage capacitor on the base substrate BS, and is non-overlapping with an orthographic projection of the respective first voltage supply line Vdd on the base substrate BS. The orthographic projection of the second main part MP2 on the base substrate BS at least partially overlaps with the orthographic projection of a second electrode Dd of the driving transistor Td on the base substrate BS.

In some embodiments, the first main part MP1 has a first average pad width pw1, and the second main part MP2 has a second average pad width pw2. In some embodiments, the first average pad width pw1 and the second average pad width pw2 are pad widths along a direction substantially parallel to the second direction DR2. In some embodiments, the first average pad width pw1 is greater than the second average pad width pw2.

In some embodiments, the voltage connecting pad has a T shape.

Referring to FIG. 3A to FIG. 3K, FIG. 4A to FIG. 4B, FIG. 5A to FIG. 5K, and FIG. 6A to FIG. 6B, in some embodiments, an orthographic projection of the respective first voltage supply line Vdd on the base substrate BS covers the orthographic projection of the first node connecting line Cln1 on the base substrate BS. By having this structure, interference to the first node connecting line can be reduced.

Referring to FIG. 3A to FIG. 3K, FIG. 4A to FIG. 4B, FIG. 5A to FIG. 5K, and FIG. 6A to FIG. 6B, in some embodiments, an orthographic projection of the respective first voltage supply line Vdd on a base substrate BS covers an orthographic projection of the active layers of the second transistor T2 and the first reset transistor Tr1 on the base substrate BS. By having this structure, stability of the second transistor T2 and the first reset transistor Tr1 can be enhanced.

In some embodiments, a first parasitic capacitor C1 is formed between the second semiconductor material layer SML2 and the respective first gate line. A second parasitic capacitor C2 is formed between the first node connecting line Cln1 and the respective second gate line. In some embodiments, a ratio of a capacitance of the first parasitic capacitor to a capacitance of the second parasitic capacitor is greater than 2.0, e.g., greater than 2.1, greater than 2.2, greater than 2.3, greater than 2.4, greater than 2.5, greater than 2.6, greater than 2.7, greater than 2.8, greater than 2.9, greater than 3.0, greater than 3.1, greater than 3.2, greater than 3.3, greater than 3.4, greater than 3.5, greater than 3.6, greater than 3.7, greater than 3.8, greater than 3.9, or greater than 4.0. In one example, the ratio of the capacitance of the first parasitic capacitor to the capacitance of the second parasitic capacitor is greater than 2.3. In another example, the ratio of the capacitance of the first parasitic capacitor to the capacitance of the second parasitic capacitor is between 2.3 to 3.5. The inventors of the present disclosure discover that a higher ratio of C₁ to C₂ is conducive to achieving an increased dark state margin. By having the ratio between 2.3 to 3.5, the array substrate can achieve an increased dark state margin, and at the same time makes full use of the layout space.

In some embodiments, the respective first gate line comprises a respective first gate line first branch GL1-1 in a first gate metal layer Gate1 and a respective first gate line second branch GL1-2 in a first signal line layer SD1 on a side of the first gate metal layer Gate1 away from the base substrate BS. The respective first gate line second branch GL1-2 is connected to the respective first gate line first branch GL1-1 through one or more vias. The first parasitic capacitor C1 is formed between the second semiconductor material layer SML2 and the respective first gate line first branch GL1-1 and between the second semiconductor material layer SML2 and the respective first gate line second branch GL1-2. Optionally, the capacitance of the first parasitic capacitor is greater than at least twice of the capacitance of the second parasitic capacitor. By having the respective first gate line first branch GL1-1 and the respective first gate line second branch GL1-2, the resistance of the respective first gate line can be reduced.

FIG. 14 is a cross-sectional view along an F-F′ line in FIG. 3A. Referring to FIG. 14, the first capacitor C1 is denoted in the cross-sectional view. The second capacitor C2 is denoted in FIG. 4B, FIG. 6B, and FIG. 8.

In another aspect, the present invention provides a display apparatus, including the array substrate described herein or fabricated by a method described herein, and one or more integrated circuits connected to the array substrate. Examples of appropriate display apparatuses include, but are not limited to, an electronic paper, a mobile phone, a tablet computer, a television, a monitor, a notebook computer, a digital album, a GPS, etc. Optionally, the display apparatus is an organic light emitting diode display apparatus. Optionally, the display apparatus is a micro light emitting diode display apparatus. Optionally, the display apparatus is a mini light emitting diode display apparatus.

In another aspect, the present disclosure provides a method of fabricating an array substrate. In some embodiments, the method includes forming a plurality of pixel driving circuits, forming a plurality of first voltage supply lines, and forming a plurality of light emitting control signal lines. Optionally, forming a respective pixel driving circuit of the plurality of pixel driving circuits comprises forming a driving transistor, forming a first light emitting control transistor, forming a storage capacitor, and forming a voltage connecting pad. Optionally, forming the voltage connecting pad comprises forming a main portion and forming an extension portion extending away from the main portion. Optionally, the main portion connects a respective first voltage supply line of the plurality of first voltage supply lines with a second capacitor electrode of the storage capacitor. Optionally, the extension portion connects the main portion with a first electrode of the first light emitting control transistor. Optionally, the extension portion crosses over a respective light emitting control signal line of the plurality of light emitting control signal lines.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. An array substrate, comprising a plurality of first gate lines, a plurality of second gate lines, and a plurality of pixel driving circuits;
wherein a respective pixel driving circuit of the plurality of pixel driving circuits comprises a driving transistor, a data write transistor, a compensating transistor, a storage capacitor, a first node connecting line connecting a gate electrode of the driving transistor with a first electrode of the compensating transistor;
a respective first gate line of the plurality of first gate lines configured to provide a gate scanning signal to the data write transistor;
a respective second gate line of the plurality of second gate lines configured to provide a gate scanning signal to the compensating transistor;
wherein the array substrate comprises a first semiconductor material layer and a second semiconductor material layer on a side of the first semiconductor material layer away from a base substrate;
the first semiconductor material layer comprises at least active layers of the driving transistor and the data write transistor;
the second semiconductor material layer comprises at least an active layer of the compensating transistor;
a first parasitic capacitor is formed between the second semiconductor material layer and the respective first gate line;
a second parasitic capacitor is formed between the first node connecting line and the respective second gate line;
wherein a ratio of a capacitance of the first parasitic capacitor to a capacitance of the second parasitic capacitor is greater than 2.3.

2. The array substrate of claim 1, wherein the ratio of the capacitance of the first parasitic capacitor to the capacitance of the second parasitic capacitor is between 2.3 to 3.5.

3. The array substrate of claim 1, wherein the first node connecting line crosses over the respective second gate line;
in a region where an orthographic projection of the first node connecting line on the base substrate overlaps with an orthographic projection of the respective second gate line on the base substrate, the array substrate is absent of any other conductive component whose orthographic projection on the base substrate overlaps with the orthographic projection of the first node connecting line on the base substrate; and
the first node connecting line is in a layer that is spaced apart from the respective second gate line by at least two different insulating layers and a semiconductor material layer.

4. The array substrate of claim 3, wherein the respective pixel driving circuit further comprises a third gate electrode pad, and a gate connecting pad connecting the third gate electrode pad with the respective second gate line;
orthographic projections of the third gate electrode pad and the respective second gate line on the base substrate overlap with an orthographic projection of an active layer of the compensating transistor on the base substrate; and
the third gate electrode pad, the gate connecting pad, and the respective second gate line, and the active layer of the compensating transistor are in four different layers, respectively.

5. The array substrate of claim 4, wherein the respective second gate line is in a second gate metal layer comprising a second capacitor electrode of the storage capacitor;
the active layer of the compensating transistor is in the second semiconductor material layer on a side of the second gate metal layer away from the base substrate;
the third gate electrode pad is in a third gate metal layer on a side of the second semiconductor material layer away from the second gate metal layer; and
the gate connecting pad is in a first signal line layer on a side of the third gate metal layer away from the second semiconductor material layer.

6. The array substrate of claim 4, wherein the gate connecting pad is in a second gate metal layer comprising a second capacitor electrode of the storage capacitor;
the active layer of the compensating transistor is in the second semiconductor material layer on a side of the second gate metal layer away from the base substrate;
the third gate electrode pad is in a third gate metal layer on a side of the second semiconductor material layer away from the second gate metal layer; and
the respective second gate line is in a first signal line layer on a side of the third gate metal layer away from the second semiconductor material layer.

7. The array substrate of claim 3, wherein the respective second gate line is in a second gate metal layer comprising a second capacitor electrode of the storage capacitor;
the first electrode of the compensating transistor is in the second semiconductor material layer on a side of the second gate metal layer away from the base substrate; and
the first node connecting line is in a first signal line layer on a side of the second semiconductor material layer away from the second gate metal layer.

8. The array substrate of claim 3, wherein the first node connecting line is in a first gate metal layer comprising a first capacitor electrode of the storage capacitor;
the first electrode of the compensating transistor is in the second semiconductor material layer on a side of the first gate metal layer away from the base substrate; and
the respective second gate line is in a first signal line layer on a side of the second semiconductor material layer away from the first gate metal layer.

9. The array substrate of claim 8, wherein the first node connecting line and the first capacitor electrode are parts of a unitary structure.

10. The array substrate of claim 8, wherein the respective pixel driving circuit further comprises a node connecting pad in the first signal line layer comprising the respective second gate line; and
the node connecting pad connects the first node connecting line in the first gate metal layer with the first electrode of the compensating transistor in the second semiconductor material layer.

11. The array substrate of claim 10, wherein the node connecting pad is connected to the first node connecting line through an eighth via, and connected to the first electrode of the compensating transistor through a seventh via;
the seventh via extends through a passivation layer and a second inter-layer dielectric layer; and
the eighth via extends through the passivation layer, the second inter-layer dielectric layer, a first inter-layer dielectric layer, and an insulating layer.

12. The array substrate of claim 3, wherein the respective second gate line comprises a first portion and a second portion;
an orthographic projection of the first portion on the base substrate at least partially overlaps with an orthographic projection of an active layer of the compensating transistor on the base substrate, and is non-overlapping with an orthographic projection of the first node connecting line on the base substrate;
an orthographic projection of the second portion on the base substrate at least partially overlaps with the orthographic projection of the first node connecting line on the base substrate, and is non-overlapping with an orthographic projection of the active layer of the compensating transistor on the base substrate;
the respective second gate line extends along a first direction;
the first portion has a first average line width where the first portion crosses over the active layer of the compensating transistor, along a second direction perpendicular to the first direction;
the second portion has a second average line width where the second portion crosses over the first connecting line, along the second direction; and
the first average line width is greater than the second average line width.

13. The array substrate of claim 1, further comprising a plurality of first voltage supply lines and a plurality of light emitting control signal lines;
wherein a respective pixel driving circuit of the plurality of pixel driving circuits comprises a first light emitting control transistor, and a voltage connecting pad;
wherein the voltage connecting pad comprises a main portion and an extension portion extending away from the main portion;
the main portion connects a respective first voltage supply line of the plurality of first voltage supply lines with a second capacitor electrode of the storage capacitor;
the extension portion connects the main portion with a first electrode of the first light emitting control transistor; and
the extension portion crosses over a respective light emitting control signal line of the plurality of light emitting control signal lines.

14. The array substrate of claim 13, wherein the main portion includes a first main part and a second main part;
the first main part connects the respective first voltage supply line with the second capacitor electrode;
an orthographic projection of the first main part on a base substrate at least partially overlaps with an orthographic projection of the second capacitor electrode on the base substrate, and at least partially overlaps with an orthographic projection of the respective first voltage supply line on the base substrate;
an orthographic projection of the second main part on the base substrate is non-overlapping with an orthographic projection of the second capacitor electrode on the base substrate, is non-overlapping with an orthographic projection of the respective first voltage supply line on the base substrate, and at least partially overlaps with an orthographic projection of a second electrode of the driving transistor on the base substrate;
the first main part has a first average pad width along a direction substantially parallel to the second direction;
the second main part has a second average pad width along the direction substantially parallel to the second direction; and
the first average pad width is greater than the second average pad width.

15. The array substrate of claim 14, wherein the respective light emitting control signal line is in a first gate metal layer;
the main portion and the extension portion are in a first signal line layer on a side of the first gate metal layer away from the base substrate;
the respective first voltage supply line is in a second signal line layer on a side of the first signal line layer away from the first gate metal layer;
the respective first voltage supply line is connected to the first main part through a third via extends through a first planarization layer; and
the first main part is connected to the second capacitor electrode through a fourth via extending through a passivation layer, a second inter-layer dielectric layer, and a first inter-layer dielectric layer.

16. The array substrate of claim 13, wherein an orthographic projection of the respective first voltage supply line on the base substrate covers the orthographic projection of the first node connecting line on the base substrate.

17. The array substrate of claim 13, wherein the respective pixel driving circuit further comprises a first reset transistor;
active layers of the compensating transistor and the first reset transistor are in a second semiconductor material layer; and
an orthographic projection of the respective first voltage supply line on a base substrate covers an orthographic projection of the active layers of the compensating transistor and the first reset transistor on the base substrate.

18. The array substrate of claim 13, further comprising a plurality of second voltage supply lines, a plurality of fourth reset signal lines, and a plurality of data lines in a same layer as the plurality of first voltage supply lines;
the plurality of pixel driving circuits are arranged in columns, including (2k-1)-th column C(2k-1), and (2k)-th column C(2k) of K columns, K and k being positive integers, 1≤k≤K/2;
the plurality of fourth reset signal lines are present in the (2k-1)-th column C(2k-1), and are absent in the (2k)-th column C(2k); and
the plurality of second voltage supply lines are present in the (2k)-th column C(2k), and are absent in the (2k-1)-th column C(2k-1).

19. (canceled)

20. An array substrate, comprising a plurality of first gate lines, a plurality of second gate lines, and a plurality of pixel driving circuits;
wherein a respective pixel driving circuit of the plurality of pixel driving circuits comprises a driving transistor, a data write transistor, a compensating transistor, a storage capacitor, a first node connecting line connecting a gate electrode of the driving transistor with a first electrode of the compensating transistor;
a respective first gate line of the plurality of first gate lines configured to provide a gate scanning signal to the data write transistor;
a respective second gate line of the plurality of second gate lines configured to provide a gate scanning signal to the compensating transistor;
wherein the array substrate comprises a first semiconductor material layer and a second semiconductor material layer on a side of the first semiconductor material layer away from a base substrate;
the first semiconductor material layer comprises at least active layers of the driving transistor and the data write transistor;
the second semiconductor material layer comprises at least an active layer of the compensating transistor;
a first parasitic capacitor is formed between the second semiconductor material layer and the respective first gate line;
a second parasitic capacitor is formed between the first node connecting line and the respective second gate line;
the respective first gate line comprises a respective first gate line first branch in a first gate metal layer and a respective first gate line second branch in a first signal line layer on a side of the first gate metal layer away from the base substrate;
the respective first gate line second branch is connected to the respective first gate line first branch through one or more vias;
the first parasitic capacitor is formed between the second semiconductor material layer and the respective first gate line first branch and between the second semiconductor material layer and the respective first gate line second branch; and
a capacitance of the first parasitic capacitor is greater than at least twice of a capacitance of the second parasitic capacitor.

21. A display apparatus, comprising the array substrate of claim 1, and one or more integrated circuits connected to the array substrate.
